(19) United States
(12) Patent Application Publication
(10) Pub. No.: US 2024/0023348 A1
(43) Pub. Date: Jan. 18, 2024

(54) Graphene Nanoribbon Photovoltaics

(71) Applicants: Board of Trustees of Michigan State University, East Lansing, MI (US); Board of Regents of the Nevada system of Higher Educationon behalf of the University of Nevada, Reno, Reno, NV (US)

(72) Inventors: Richard Royal LUNT, III, Williamston, MI (US); Matthew BATES, East Lansing, MI (US); Ryan J. MALONE, Edmonton (CA); Wesley A. CHALIFOUX, Edmonton (CA)

(21) Appl. No.: 18/222,944

(22) Filed: Jul. 17, 2023

Related U.S. Application Data
(60) Provisional application No. 63/389,873, filed on Jul. 16, 2022.

(51) Int. Cl. H10K 30/50; H10K 30/20; H10K 85/20

(52) U.S. Cl. CPC H10K 30/50; H10K 30/20; H10K 85/211

(57) ABSTRACT

A photovoltaic device includes a substrate, a first electrode on a surface of the substrate, a second electrode, and a first photoactive layer between the first electrode and the second electrode. The first photoactive layer includes graphene nanoribbons (GNRs).

### CROSS-REFERENCE TO RELATED APPLICATIONS

This application claims the benefit of U.S. Provisional Patent Application 63/389,873, filed Jul. 16, 2022. This application is related to PCT Patent Application No. PCT/US23/27933, Attorney Docket No. 6550-000444-WO-POA and PCT Patent Application No. PCT/US23/27919, Attorney Docket No. 6550-000445-WO-POA, both filed simultaneously on Jul. 17, 2023. The entire disclosures of each of the above applications are incorporated herein by reference.

### GOVERNMENT RIGHTS

This invention was made with government support under CHE-2102107 and CHE-1555218 awarded by the National Science Foundation. The government has certain rights in the invention.

### FIELD

The present disclosure relates to photovoltaics including graphene nanomaterials in photoactive layers.

### BACKGROUND

This section provides background information related to the present disclosure which is not necessarily prior art.

Graphene materials possess outstanding electrical and mechanical properties, including room temperature carrier mobilities greater than 15,000 cm²V⁻¹s⁻¹, a conductivity greater than that of silver, a Young's modulus of 1 TPa, and tensile strength of 50-60 GPa. Given its above properties, there is interest in the use of graphene for electronic and optoelectronic applications, including in photovoltaic devices (PVs).

### SUMMARY

This section provides a general summary of the disclosure, and is not a comprehensive disclosure of its full scope or all of its features.

A new graphitic material, graphene GNRs, is used in PV devices as an active material.

Graphene has received a great deal of research interest for electronic applications due to its excellent electronic and mechanical properties. While two-dimensional graphene is a zero-bandgap semiconductor, GNRs are one-dimensional graphene materials with a bandgap defined by ribbon width. Despite advances in bottom-up synthesis that yield a range of nanoribbon widths and bandgaps, the application of graphene and GNRs has been largely limited to conductive interlayers and electrodes for photovoltaics. In this example, the use of GNRs as the photoactive layer in photovoltaic applications is demonstrated. GNRs are fabricated using nonoxidative alkyne benzannulation synthesis for precise GNR width control. PV cells are fabricated utilizing GNRs as a donor photoactive material generating photocurrent across the solar spectrum, from the ultraviolet region to past 1000 nm in the near-infrared. Interference modeling is used to demonstrate limitations of GNR devices which are constrained by charge collection and charge hopping between ribbons. This example ultimately shows that graphene and GNRs can function as a photoactive optoelectronic material in photovoltaic devices, expanding the potential of all-graphitic electronics.

At least one example embodiment relates to a photovoltaic device.

In at least one example embodiment, the photovoltaic device includes a substrate, a first electrode on a surface of the substrate, a second electrode, and a first photoactive layer between the first electrode and the second electrode. The first photoactive layer includes graphene nanoribbons (GNRs).

In at least one example embodiment, the first photoactive layer is neat.

In at least one example embodiment, the first photoactive layer includes GNRs admixed with another photoactive material.

In at least one example embodiment, the first photoactive layer defines a thickness ranging from 2 nm to 1000 nm.

In at least one example embodiment, the GNR is a semiconductor.

In at least one example embodiment, at least a portion of the GNRs include edge groups.

In at least one example embodiment, the edge groups include hydrogen, a halogen, an alkyl chain, or a thiophene chain, or any combination thereof.

In at least one example embodiment, the edge groups include

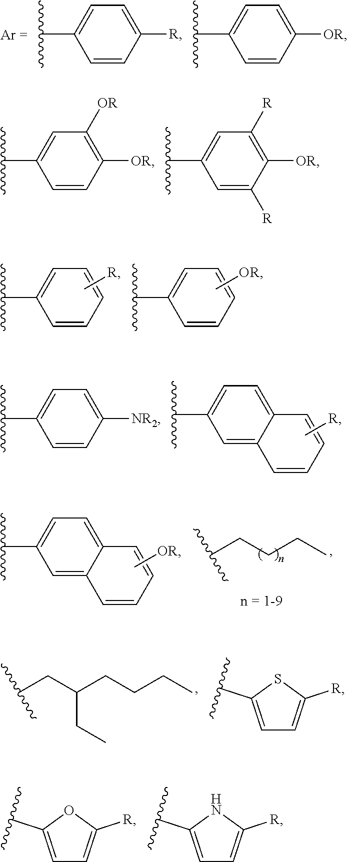

or any combination thereof.

In at least one example embodiment, the GNRs have an external quantum efficiency (EQE) of greater than or equal to 0.5%.

In at least one example embodiment, the device further includes a second photoactive layer.

In at least one example embodiment, the second photoactive layer defines a thickness ranging from 5 nm to 200 nm.

In at least one example embodiment, the first photoactive layer is a donor layer, and the second photoactive layer is an acceptor layer.

In at least one example embodiment, second photoactive layer includes C60.

In at least one example embodiment, the first photoactive layer is an acceptor layer, and the second photoactive layer is a donor layer.

In at least one example embodiment, the first photoactive layer consists essentially of GNRs.

In at least one example embodiment, the first photoactive layer has an exciton diffusion length ranging from 10 nm to 300 nm.

In at least one example embodiment, the first photoactive layer has a charge collection length ranging from 10 nm to 10,000 nm.

In at least one example embodiment, the GNRs define an average length ranging from 1 nm to 100,000 nm.

In at least one example embodiment, the GNRs define a core average width of 0.25 nm to 100 nm.

In at least one example embodiment, the GNRs have a bandgap of greater than or equal to 0.1 eV.

In at least one example embodiment, the GNRs have a bandgap of greater than or equal to 0.2 eV to less than or equal to 2.5 eV.

In at least one example embodiment, the GNRs have less than 1 edge defect per 1 nm of length.

In at least one example embodiment, each of the GNRs defines a length and a width. Each of the GNRs includes a quantity of benzene rings across the width. The quantity ranges from 1 to 100 benzene rings.

In at least one example embodiment, greater than or equal to 50% of the GNRs are oriented within 20% of perpendicular to the substrate.

In at least one example embodiment, greater than or equal to 50% of the GNRs are oriented within 20% of parallel to the substrate.

In at least one example embodiment, the device further includes an adjunct layer including a hole transport layer, an electron blocking layer, a buffer layer, an electron transport layer, a hole blocking layer, an electron extraction or any combination thereof.

In at least one example embodiment, the adjunct layer includes a hole transport layer and an electron transport layer.

At least one example embodiment relates to a photovoltaic device.

In at least one example embodiment, the photovoltaic device includes a first electrode, a second electrode, a donor layer between the first electrode and the second electrode, an acceptor layer between the donor layer and the second electrode. The donor layer includes graphene nanoribbons (GNRs). The device further includes a hole transport layer between the donor layer and the first electrode and an electron transport layer between the acceptor layer and the second electrode.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic illustration of a photovoltaic (PV) in accordance with at least one example embodiment.

FIG. 2A is a schematic showing graphene nanoribbon (GBR) orientation in accordance with at least one example embodiment. FIG. 2B is a schematic showing horizontally oriented GNRs in accordance with at least one example embodiment. FIG. 2C is a schematic showing vertically oriented GNRs in accordance with at least one example embodiment.

FIGS. 3A-3N illustrate GNR end groups in accordance with example embodiments.

FIGS. 4A-4C relate to GNR type. FIG. 4A is a schematic illustrating edge locations for various types of GNRs in accordance with at least one example embodiment. FIG. 4B is a schematic illustration showing an armchair-type GNR in accordance with at least one example embodiment. FIG. 4C is a schematic illustration of a zigzag-type GNR in accordance with at least one example embodiment.

FIGS. 5A-5E illustrate GNRs in accordance with example embodiments.

FIGS. 6A-6D relate to photoelectric effect from graphene nanoribbon thin films in photovoltaic devices. FIG. 6A is a schematic of the photoelectric effect in GNR thin films as observed in photovoltaic devices utilizing a GNR-C₆₀ bilayer active layer. FIG. 6B is a two-dimensional drawing of the GNR used in this work. FIG. 6B shows absorption (1−Transmission) of the GNR in 1,2,4-trichlorobenzene at 0.01 mg mL⁻¹ and 0.05 mg mL⁻¹, demonstrating light harvesting across the ultraviolet, visible, and near-infrared spectrums. FIG. 6D shows PV device architecture. Devices are grown on indium tin oxide patterned glass substrates, with molybdenum trioxide (MoO₃) as a hole transport layer, the GNR-C₆₀ active layer, bathocuproine (BCP) electron transport layer, and silver (Ag) top electrode.

FIG. 7 shows a synthesis pathway for GNRs.

FIGS. 8A-8C show graphene nanoribbon photovoltaic device data. FIG. 8A illustrates thickness dependent current-voltage (J-V) curves for graphene nanoribbon (GNR)-C₆₀ devices of increasing GNR thickness and for a C₆₀-only control device. FIG. 8B illustrates external quantum efficiency (EQE) data for the optimal GNR device with 3.0 nm of GNR and the C₆₀-only device. The shaded region demonstrates the photocurrent gained by including the GNR layer. The estimated GNR EQE (black) was calculated by subtracting the C₆₀-only device from the 3.0 nm GNR bilayer device. Cumulative integrated photocurrents (dashed lines) for the 3.0 nm GNR, C₆₀-only, and GNR contribution. FIG. 8C illustrates EQE in the near-infrared region of the 3.0 nm GNR device and the C₆₀ control device. The shaded region is the photocurrent gained in the near-infrared from the GNR. Error bars for J-V plots represent the standard deviation from a minimum of 5 measured devices.

FIGS. 9A-9E relate to calculation of exciton diffusion and charge collection lengths. FIG. 9A illustrates external quantum efficiency (EQE) thickness dependent data for increasing GNR thickness (data points). Simultaneous fits of GNR thickness dependent EQE from transfer matrix optical modeling with the characteristic lengths for exciton diffusion (L_{ED,D}) and charge collection (L_{CC,D}) of the GNR (solid lines). C₆₀-only device EQE was fitted separately. FIG. 9B illustrates internal quantum efficiency (IQE) calculated from experimental EQE and absorption as a function of GNR thickness. FIG. 9C illustrates IQE calculated from experimental EQE and model generated absorption. FIG. 9D illustrates hole only device data fitted with the Mott-Gurney equation for space charge limited current to extract the hole mobility for GNR thin films. FIG. 9E is a schematic illustrating the likely cause of poor charge collection efficiency in bulk GNR films relative to the expected high conductivity from graphene-based materials. While hole mobility through a single ribbon's conjugated core may be excellent, experimental data and computational calculations demonstrate poor mobility when charges must transfer between ribbons. Error bars for holy mobility data represent the standard deviation from five measured devices.

FIG. 10A illustrates raw reflection data for full device stacks grown on 1.5″×1.5″ substrates used to calculate the device absorption as 100−reflection (%). FIG. 10B illustrates absorption data (100−% Reflection) for full device stacks grown on 1.5″×1.5″ substrates with increasing thickness of GNR from 3.0 to 9.0 nm. FIG. 10C illustrates Integrated exciton generation rates of the GNR layers normalized to the thickness of the layer as a function of wavelength.

FIG. 10D illustrates integrated exciton generation rates in the GNR layer within 1 nm of the GNR-C₆₀ interface for different GNR thicknesses as a function of wavelength.

FIG. 11A is a graph illustrating exciton generation rates in a 3.0 nm GNR device stack as a function of position and excitation wavelength. FIG. 11B is a graph illustrating exciton generation rates in a 3.5 nm GNR device stack as a function of position and excitation wavelength.

FIG. 12A is a graph illustrating exciton generation rates in a 4.5 nm GNR device stack as a function of position and excitation wavelength. FIG. 12B is a graph illustrating exciton generation rates in a 6.0 nm GNR device stack as a function of position and excitation wavelength.

FIG. 13A is a graph illustrating exciton generation rates in a 7.0 nm GNR device stack as a function of position and excitation wavelength. FIG. 13B is a graph illustrating exciton generation rates in a 9.0 nm GNR device stack as a function of position and excitation wavelength.

FIGS. 14A-14D relate to calculation of graphene nanoribbon bandgap and molecular orbitals. FIG. 14A show graphene nanoribbon (GNR) used for computational calculations featuring six repeating units (6-GNR) and hydrogen terminated side chains at the oxygen atom. FIG. 14B is an energy diagram of pentacene (control), a three-unit GNR (3-GNR), 6-GNR, and C₆₀ bandgaps. Pentacene, 3-GNR, and 6-GNR bandgaps and highest occupied molecular orbital (HOMO) energy levels are adjusted based on pentacene values from literature, and C₆₀ values are pulled from literature. FIG. 14C shows calculated HOMO of 3-GNR. FIG. 14D shows calculated lowest unoccupied molecular orbital (LUMO) of 3-GNR, where shaded regions represent high electron wavefunction density. The 3-GNR HOMO and LUMO demonstrate the conjugated pathway through the core of the GNR, where shaded regions represent hihg electron wavefunction density.

FIG. 15 is a ¹H NMR spectrum for Compound 2 in CDCl₃ at 298 K in accordance with at least one example embodiment.

FIG. 16 is a ¹³C NMR spectrum for Compound 2 in CDCl₃ at 298 K in accordance with at least one example embodiment.

FIG. 17 is a ¹H NMR spectrum for Compound 4 in CDCl₃ at 298 K in accordance with at least one example embodiment.

FIG. 18 is a ¹³C NMR spectrum for Compound 4 in CDCl₃ at 298 K in accordance with at least one example embodiment.

FIG. 19 is a ¹H NMR spectrum for Compound 5 in CDCl₃ at 298 K in accordance with at least one example embodiment.

FIG. 20 is a ¹³C NMR spectrum for Compound 5 in CDCl₃ at 298 K in accordance with at least one example embodiment.

FIG. 21 is a ¹H NMR spectrum for Compound 6 in CDCl₃ at 298 K in accordance with at least one example embodiment.

FIG. 22 is a ¹³C NMR spectrum for Compound 6 in CDCl₃ at 298 K in accordance with at least one example embodiment.

FIG. 23 is a ¹H NMR spectrum for Compound 7 in CDCl₃ at 298 K in accordance with at least one example embodiment.

FIG. 24 is a ¹³C NMR spectrum for Compound 7 in CDCl₃ at 298 K in accordance with at least one example embodiment.

FIG. 25 is a ¹H NMR spectrum for Compound 8 in CDCl₃ at 298 K in accordance with at least one example embodiment.

FIG. 26 is a ¹³C NMR spectrum for Compound 8 in CDCl₃ at 298 K in accordance with at least one example embodiment.

Corresponding reference numerals indicate corresponding parts throughout the several views of the drawings.

### DETAILED DESCRIPTION

Example embodiments will now be described more fully with reference to the accompanying drawings.

Graphene can be used as a conductive layer and/or electrode in thin film PVs, organic PVS, polymer PVs, and dye sensitized PVs. Graphene is a 2-dimensional zero gap semiconductor or semi-metal, and as a result, has not previously been directly used as light harvesting or photoactive layers in PV cells. A photoactive layer is a layer including (or consisting of or consisting essentially of) a photoactive material. A photoactive material is a material that absorbs light to generate charge carriers (known as photocurrent).

Bandgap can be generated by confining graphene with a dimension lower than the Bohr radius. One dimensional graphitic materials can be synthesized with bandgaps ranging from 0.2 eV to 3.5 eV based on both top-down (e.g., unzipped carbon nanotubes or cleaved, cut, or etched graphene sheets) and bottom-up (e.g., synthesized additively) approaches. Carbon nanotubes (CNTs) are examples of one-dimensional carbon-based materials with bandgaps suitable for photovoltaics based on the nanoscale diameter of the CNT. Graphene nanoribbons (GNRs) are a new class of one-dimensional carbon material synthesized from the bottom-up with a tunable bandgap controlled by the ribbon width and minimized edge defects. GNRs offer bandgaps suitable for charge separation and close to the ideal Shockley-Queisser (SQ) theoretical limit range between 1.1 eV and 1.4 eV. Combined with low cost and low toxicity, this makes GNRs an exciting candidate for the next generation of thin film optoelectronic devices.

GNRs can be realized using top-down approaches, including CNT unzipping, graphene etching, and graphene chemical vapor deposition. GNRs synthesized from such approaches often have a wide distribution of thicknesses, shapes, and defects, and therefore widely vary in their electronic and optical properties. This variability makes PV device fabrication with top-down GNRs difficult if large diameter CNTs are unzipped to yield wide GNRs with shorting pathways. Top-down GNRs may have undesired oxide groups or other defects that negatively impact conductivity and solubility that impedes processing. Furthermore, the width of GNRs synthesized from graphene sheets or unzipping multi-walled CNTs are often too large (>10 nm) to produce a bandgap suitable for charge separation, limiting their use to non-optical applications. Thinner GNRs are possible when synthesized by unzipping single-walled CNTs, although challenges with uniformity and processability remain. A range of new bottom-up approaches can be used to synthesize GNRs with greater uniformity, improved solubility, and widths small enough to induce suitable bandgaps. One bottom-up approach using nonoxidative alkyne benzannulation yields GNRs with widths less than 5 nm and an optical bandgap (˜1 eV) on the edge of the ideal bandgap range (1.1-1.4 eV) for PVs from the SQ limit, allowing for photon absorption across the ultra-violet (UV), visible (VIS), and near-infrared (NIR) portions of the solar spectrum. Bottom-up syntheses offer control over side groups attached at the ribbon edge that greatly improve solubility and lead to facile formation of thin films for PVs via spin-coating and other solution processed deposition methods.

GNRs can be used in a variety of applications, including field effect transistors, sensors, electrochemical catalysis, batteries, and PVs. In PVs, graphene and GNRs have been utilized as transport layers and electrodes, including hole transport layers for polymer and perovskite PVs, electron transport layers in perovskite devices, and indium tin oxide replacement electrodes in polymer PVs. GNRs can also be used in Schottky solar cells as part of an electrode junction with silicon nanowires. Exciton binding energies of 1.8 eV, 1.6 eV, and 0.7 eV may be demonstrated and/or calculated for various GNRs. An exciton lifetime of over 100 ps in solution-dispersed GNRs is also possible. Accordingly, strong excitonic effects in GNRs and the long exciton lifetime is particularly promising for optoelectronic applications, but GNR implementation into optoelectronic devices as a photoactive light harvesting material has not previously been realized.

The present disclosure provides photoactive materials that include GNRs and photoactive devices including the photoactive materials. In at least one example embodiment, the photoactive material consists essentially of GNRs. The present disclosure also provides methods of making GNRs. In at least one example embodiment, the method includes nonoxidative alkyne benzannulation synthesis. In at least one example embodiment, the method includes tuning the GNRs to have a desired (or alternatively, predetermined) bandgap by controlling physical characteristics of the GNRs, such as width and/or bandgap.

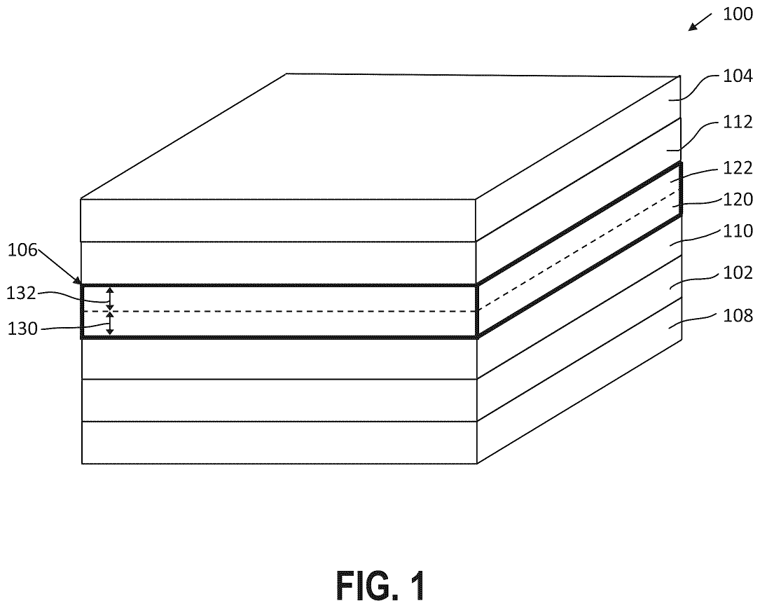

FIG. 1 illustrates a photovoltaic (PV) 100 in accordance with at least one example embodiment. The PV 100 generally includes a first electrode 102, a second electrode 104, and a photoactive layer 106 between the first and second electrodes 102, 104. In at least one example embodiment, one or both of the first and second electrodes 102, 104 may be on a substrate 108. In at least one example embodiment, the first electrode 102 may be positioned on the substrate 108 and include materials that act as the electrode, such that the substrate and electrode are visibly indistinguishable (not shown).

In at least one example embodiment, the electrodes 102, 104 may include thin metal (e.g., Ag, Au, Al, and/or Cu), indium tin oxide (ITO), tin oxide, aluminum doped zinc oxide, metallic nanotubes, metal nanowires (e.g., Ag, Au, Al, and/or Cu), conductive carbon nanotubes, graphene, conductive low-e stack, conductive polymers (e.g. poly(3,4-ethylenedioxythiophene) polystyrene sulfonate (PEDOT:PSS)), conducting organic salts (e.g. tetrathiofulvalenium-7,7,8,8-tetracyanoquinodimethanide (TTF-TCNQ)), low-e single-silver stack, low-e double-silver stack, low-e triple-silver stack, or any combination thereof. In at least one example embodiments, one or both of the electrodes 102, 104 are transparent.

The substrate 108 may be transparent or opaque. In at least one example embodiment, the substrate 108 includes glass, plastic (e.g., polythethylene, polycarbonate, polymethyl methacrylate, and/or polydimethylsiloxane), or any combination thereof.

In at least one example embodiment, the PV 100 further includes or more adjunct layers, such as a first adjunct layer 110 and a second adjunct layer 112. In the example embodiment shown, the first adjunct layer 110 is between the first electrode 102 and the photoactive layer 106. The second adjunct layer 112 is between the second electrode 104 and the photoactive layer 106. Each of the adjunct layers 110, 112 may include a hole transport layer, an electron blocking layer, a buffer layer, an electron transport layer, a hole blocking layer, an electron extraction layer, or any combination thereof. Although the example embodiment of FIG. 1 shows two adjunct layers 110, 112, a PV in accordance with the present disclosure may be free of adjunct layers, include a single adjunct layer, or include more than two adjunct layers. In at least one example embodiment, the first adjunct layer is a hole transport layer and the second adjunct layer is an electron transport layer. In at least one other example embodiment, the first adjunct layer is an electron transport layer and the second adjunction layer is hole transport layer. In at least one other example embodiment, the first and second adjunct layers may be a conducting or semiconducting wetting layer. In at least one other example embodiment, the first and second adjunct layers may be hole or electron blocking layers. In at least one example embodiment, the adjunct layers may have compositions as described in PCT Patent Application No. PCT/US2019/030209, filed on May 1, 2019, and published as WO2019213265A1, which is incorporated herein by referenced in its entirety.

The active layer 106 includes GNRs. In at least one example embodiment, as shown, the active layer 106 includes a first or donor layer 120 and a second or acceptor layer 122. One of the donor and acceptor layers 120, 122 includes GNRs. Materials that are ambipolar (i.e., conductive to both holes and electrons) can acts as a donor or acceptor depending on the relative HOMO-LUMO positioning. GNRs can act as donor or acceptor materials. If the GNR has lower (deeper) energy levels (relative to the vacuum level) than the opposing material, then it can act as an acceptor. If the GNR has high higher energy levels to the opposing material, than the opposing material, then it can act a donor. In at least one example embodiment, the GNR is a semiconductor.

In at least one example embodiment, the donor layer 120 includes GNRs that function as a donor and the acceptor layer 122 includes a non-GNR acceptor (e.g., C60). In at least one other example embodiment, the donor layer 120 includes a non-GNR donor (e.g., a phthalocyanine, a porphyrin, cyanine, a non-fullerene acceptor, a small molecule, a polymer, or any combination thereof) and the acceptor layer 122 includes GNRs that function as an acceptor. In at least one other example embodiment, both the donor layer and the acceptor layer include GNRs of different width, shape, and/or configuration.

In at least one example embodiment, a photoactive layer (e.g., donor or accepter) includes GNRs and another material. The other material may be a photoactive material or a non-photoactive material. In at least one example embodiment, the GNRs are polymer-wrapped. In at least one example embodiment, a layer including the GNRs consists essentially of the GNRs.

In at least one example embodiment, the donor layer 120 includes a photoactive material including GNRs, phthalocynine(s), cyanine(s), coumarin, pophyrin, naphthalocyanine, squaraine, perylene, thiohphene, acene, BODIPY, rhodamine(s), quinine(s), xanthene(s), naphthalene(s), oxadiazole(s), oxazine(s), acridine(s), arylmethine(s), tetrapyrrole(s), indocarbocyanine(s), oxacarbocyanine(s), thiacarbocyanine(s), merocyanine(s) or any combination thereof.

In at least one example embodiment, the donor layer 120 defines a first thickness 130 of greater than or equal to about 5 nm (e.g., greater than or equal to about 10 nm, greater than or equal to about 15 nm, greater than or equal to about 20 nm, greater than or equal to about 25 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, greater than or equal to about 175 nm, greater than or equal to about 200, greater than or equal to about 300 nm, greater than or equal to about 400 nm, greater than or equal to about 500 nm, greater than or equal to about 600 nm, greater than or equal to about 700 nm, greater than or equal to about 800 nm, or greater than or equal to about 900 nm). The first thickness 130 may be less than or equal to about 1,000 nm (e.g., less than or equal to about 900 nm, less than or equal to about 800 nm, less than or equal to about 700 nm, less than or equal to about 600 nm, less than or equal to about 500 nm, less than or equal to about 400 nm, less than or equal to about 300 nm, less than or equal to about 200 nm, less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, or less than or equal to about 10 nm). In at least one example embodiment, the donor layer 120 consists essentially of GNRs. In at least one other example embodiment, the donor layer 120 includes GNRs and one or more other donor materials. In at least one other example embodiment, the donor layer 120 is substantially free of GNRs.

In at least one example embodiment, the donor layer 120 is continuous. As used herein, “continuous” means extending across an entire electrode or other layer and not in an island/sea configuration). In at least one example embodiment, the donor layer 120 is a continuous mesh. In at least one example embodiment, the donor layer 120 is neat. As used herein, “neat” means effectively uniform in composition (as opposed to doped or mixed) and/or that the material is deposited only of itself. In at least one example embodiment, the donor layer 120 consists essentially of a photoactive donor material. In at least one example embodiment, the first thickness 130 is substantially constant or uniform. In at least one example embodiment, the donor layer 120 is substantially uniform in composition. In at least one example embodiment, the donor layer 120 is smooth. As used herein, “smooth” means having a roughness of less than about one tenth.

In at least one example embodiment, the acceptor layer 122 includes GNRs, C60, C70, C84, carbon nanotubes, TiO₂, NiO, ZnO, MoO₃, non-fullerene acceptor(s), lead-free halide perovskite(s), or any combination thereof. In at least one example embodiment, the acceptor layer 122 defines a second thickness 132 of greater than or equal to about 5 nm (e.g., greater than or equal to about 10 nm, greater than or equal to about 15 nm, greater than or equal to about 20 nm, greater than or equal to about 25 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, greater than or equal to about 175 nm, greater than or equal to about 200, greater than or equal to about 300 nm, greater than or equal to about 400 nm, greater than or equal to about 500 nm, greater than or equal to about 600 nm, greater than or equal to about 700 nm, greater than or equal to about 800 nm, or greater than or equal to about 900 nm). The second thickness 132 may be less than or equal to about 1,000 nm (e.g., less than or equal to about 900 nm, less than or equal to about 800 nm, less than or equal to about 700 nm, less than or equal to about 600 nm, less than or equal to about 500 nm, less than or equal to about 400 nm, less than or equal to about 300 nm, less than or equal to about 200 nm, less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, or less than or equal to about 10 nm). In at least one example embodiment, the acceptor layer 122 consists essentially of GNRs. In at least one other example embodiment, the acceptor layer 122 includes GNRs and one or more other acceptor materials.

In at least one other example embodiment, the acceptor layer 122 is substantially free of GNRs. In at least one example embodiment, the acceptor layer 122 is continuous. In at least one example embodiment, the acceptor layer 122 is neat. In at least one example embodiment, the second thickness 132 is substantially constant or uniform. In at least one example embodiment, the acceptor layer 122 is substantially uniform in composition.

As used herein, “exciton diffusion length” means the average distance over which an exciton will diffuse before it is annihilated to form heat or light. It is similar to, or synonymous with, the root mean square displacement of the exciton over the natural lifetime of the exciton. In at least one example embodiment, the active layer 106 has an exciton diffusion length of greater than or equal to about 10 nm (e.g., greater than or equal to about 20 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, greater than or equal to about 175 nm, greater than or equal to about 200 nm, greater than or equal to about 225 nm, or greater than or equal to about 250 nm). The exciton diffusion length may be less than or equal to about 300 nm (e.g., less than or equal to about 250 nm, less than or equal to about 225 nm, less than or equal to about 200 nm, less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 20 nm, or less than or equal to about 10 nm).

As used herein, “charge collection length” means the length over which the charge can be readily collected before it is trapped or annihilated. In at least one example embodiment, the active layer 106 has a charge collection length of greater than or equal to about 10 nm (e.g., greater than or equal to about 20 nm, greater than or equal to about 30 nm, greater than or equal to about 40 nm, greater than or equal to about 50 nm, greater than or equal to about 75 nm, greater than or equal to about 100 nm, greater than or equal to about 200 nm, greater than or equal to about 300 nm, greater than or equal to about 400 nm, greater than or equal to about 500 nm, greater than or equal to about 600 nm, greater than or equal to about 700 nm, greater than or equal to about 800 nm, greater than or equal to about 900 nm, greater than or equal to about 1,000 nm, greater than or equal to about 1,500 nm, greater than or equal to about 2,000 nm, greater than or equal to about 2,500 nm, greater than or equal to about 3,000 nm, greater than or equal to about 4,000 nm, greater than or equal to about 5,000 nm, or greater than or equal to about 7,500 nm). The charge collection length may be less than or equal to about 10,000 nm (e.g. less than or equal to about 7,500 nm, less than or equal to about 5,000 nm, less than or equal to about 4,000 nm, less than or equal to about 3,000 nm, less than or equal to about 2,500 nm, less than or equal to about 2,000 nm, less than or equal to about 1,500 nm, less than or equal to about 1,000 nm, less than or equal to about 900 nm, less than or equal to about 800 nm, less than or equal to about 700 nm, less than or equal to about 600 nm, less than or equal to about 500 nm, less than or equal to about 400 nm, less than or equal to about 300 nm, less than or equal to about 200 nm, less than or equal to about 100 nm, less than or equal to about 50 nm, less than or equal to about 40 nm, less than or equal to about 30 nm, or less than or equal to about 20 nm).

Each of the GNRs in the active layer 106 defines a length or major dimension and a width or minor dimension, with the length being greater than the width. The GNRs collectively define an average length. Each of the GNRs defines a widest width and a core width. As used herein, “core width” means width not including edge or solubilizing groups. The GNRs collectively define an average core GNR width.

In at least one example embodiment, the average GNR length is greater than or equal to about 1 nm (e.g., greater than or equal to about 5 nm, greater than or equal to about 10 nm, greater than or equal to about 15 nm, greater than or equal to about 20 nm, greater than or equal to about 50 nm, greater than or equal to about 100 nm, greater than or equal to about 200 nm, greater than or equal to about 500 nm, greater than or equal to about 1,000 nm, greater than or equal to about 5,000 nm, or greater than or equal to about 50,000 nm). The average GNR length may be less than or equal to about 100,000 nm (e.g., less than or equal to about 50,000 nm, less than or equal to about 10,000 nm, less than or equal to about 5,000 nm, less than or equal to about 1,000 nm, less than or equal to about 500 nm, less than or equal to about 200 nm, less than or equal to about 100 nm, less than or equal to about 50 nm, less than or equal to about 20 nm, less than or equal to about 15 nm, less than or equal to about 10 nm, or less than or equal to about 5 nm).

In at least one example embodiment, the average core GNR width is greater than or equal to about 0.25 nm (e.g., greater than or equal to about 0.5 nm, greater than or equal to about 0.6 nm, greater than or equal to about 1 nm, greater than or equal to about 1.5 nm, greater than or equal to about 2 nm, greater than or equal to about 2.5 nm, greater than or equal to about 3 nm, greater than or equal to about 4 nm, greater than or equal to about 5 nm, greater than or equal to about 7 nm, greater than or equal to about 10 nm, greater than or equal to about 15 nm, greater than or equal to about 20 nm, greater than or equal to about 25 nm, greater than or equal to about 30 nm, greater than or equal to about 35 nm, greater than or equal to about 40 nm, greater than or equal to about 50 nm, or greater than or equal to about 75 nm). The average core GNR width may be less than or equal to about 100 nm (e.g., less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, less than or equal to about 10 nm, less than or equal to about 7 nm, less than or equal to about 5 nm, less than or equal to about 4 nm, less than or equal to about 3 nm, less than or equal to about 2.5 nm, less than or equal to about 2 nm, less than or equal to about 1.5 nm, less than or equal to about 1 nm, or less than or equal to about 0.5 nm).

In at least one example embodiment, the GNRs have a widest width of greater than or equal to 1 benzene ring (e.g., greater than or equal to 2 benzene rings, greater than or equal to 3 benzene rings, greater than or equal to 4 benzene rings, greater than or equal to 5 benzene rings, greater than or equal to 10 benzene rings, greater than or equal to 15 benzene rings, greater than or equal to 20 benzene rings, greater than or equal to 50 benzene rings, or greater than or equal to 75 benzene rings). The GNR widest width may be less than or equal to 100 nm benzene rings (e.g., less than or equal to 75 benzene rings, less than or equal to 50 benzene rings, less than or equal to 20 benzene rings, less than or equal to 15 benzene rings, less than or equal to 10 benzene rings, less than or equal to 5 benzene rings, less than or equal to 4 benzene rings, less than or equal to 3 benzene rings, or less than or equal to 2 benzene rings).

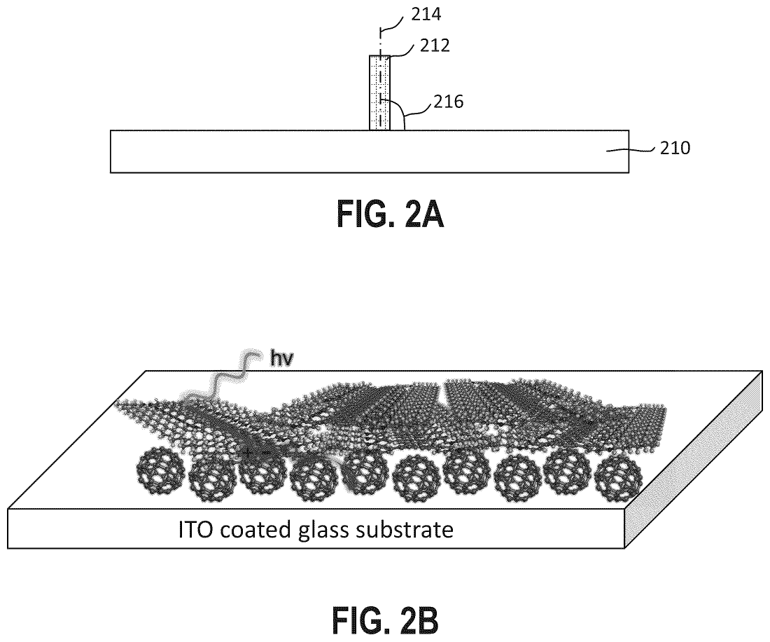

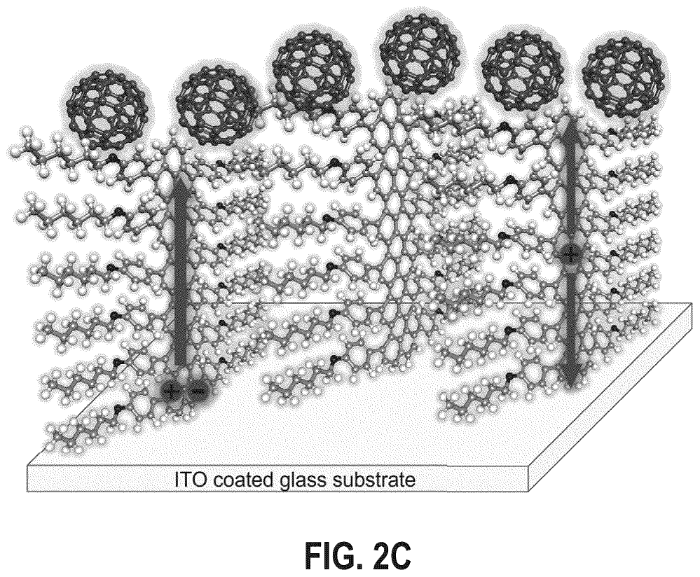

GNRs may be arranged such that they define an orientation with respect to a plane of the substrate 108 and/or electrodes 102, 104. With reference to FIG. 2A, an example substrate 210 and GNR 212 are illustrated. The GNR 212 may extend along a longitudinal axis 214 defined parallel to its length. An angle 216 is defined between the substrate 210 and GNR 212. In at least one example embodiment, an angle may be defined between each GNR and the substrate 108 and/or electrodes 102, 104. The angle may generally, or on average, be in a range of 0° with respect to the substrate 108 and/or electrodes 102, 104 (horizontal) to 90° (vertical) with respect to the substrate 108 and/or electrodes 102, 104.

In at least one example embodiment, the GNR angle is, on average, greater than or equal to about 0° (e.g., greater than or equal to about 5°, greater than or equal to about 10°, greater than or equal to about 20°, greater than or equal to about 30°, greater than or equal to about 40°, greater than or equal to about 50°, greater than or equal to about 60°, greater than or equal to about 70°, greater than or equal to about 80°). The average GNR angle may be less than or equal to about 90° (e.g., less than or equal to about 80°, less than or equal to about 70°, less than or equal to about 60°, less than or equal to about 50°, less than or equal to about 40°, less than or equal to about 30°, less than or equal to about 20°, or less than or equal to about 10°).

In at least one example embodiment, a majority of the GNRs may be at an angle of greater than or equal to about 0° (e.g., greater than or equal to about 5°, greater than or equal to about 10°, greater than or equal to about 20°, greater than or equal to about 30°, greater than or equal to about 40°, greater than or equal to about 50°, greater than or equal to about 60°, greater than or equal to about 70°, greater than or equal to about 80°). The majority of the GNRs may be at an angle of less than or equal to about 90° (e.g., less than or equal to about 80°, less than or equal to about 70°, less than or equal to about 60°, less than or equal to about 50°, less than or equal to about 40°, less than or equal to about 30°, less than or equal to about 20°, or less than or equal to about 10°).

In at least one other example embodiment, substantially all of the GNRs are oriented substantially parallel to the substrate 108 and/or electrodes 102, 104 (shown in FIG. 1). For example, at least 50% of the GNRs are oriented within 20° of horizontal. FIG. 2B is a schematic view GNRs oriented parallel to a substrate in accordance with at least one example embodiment.

In at least one example embodiment, substantially all of the GNRs are oriented substantially perpendicular to the substrate 108 and/or electrodes 102, 104. For example, at least 50% of the GNRs are oriented within 20° of vertical. FIG. 2C is a schematic view GNRs oriented perpendicular to a substrate in accordance with at least one example embodiment.

As used herein, “edge defect” means a bonding defect (e.g., vacancy and/or unintended chemical substitution) in the edge-most graphitic carbon lattice. In at least one example embodiment, the GNRs have, on average, less than 1 edge defect per about 1 nm of length (e.g., less than 1 edge defect per about 2 nm of length, less than 1 edge defect per about 5 nm of length, less than 1 edge defect per about 10 nm of length, less than 1 edge defect per about 15 nm of length, less than 1 edge defect per about 20 nm of length, less than 1 edge defect per about 50 nm of length, less than 1 edge defect per about 100 nm of length, or less than 1 edge defect per about 200 nm of length). In at least one example embodiment, the GNRs are substantially free of oxide groups.

As used herein, “core defect” means a bonding defect (e.g., vacancy and/or unintended chemical substitution) in the core graphitic carbon lattice of the GNR. In at least one example embodiment, the GNRs have, on average, less than 1 core defect per about 1 nm of length (e.g., less than 1 core defect per about 2 nm of length, less than 1 core defect per about 5 nm of length, less than 1 core defect per about 10 nm of length, less than 1 core defect per about 15 nm of length, less than 1 core defect per about 20 nm of length, less than 1 core defect per about 50 nm of length, less than 1 core defect per about 100 nm of length, or less than 1 core defect per about 200 nm of length).

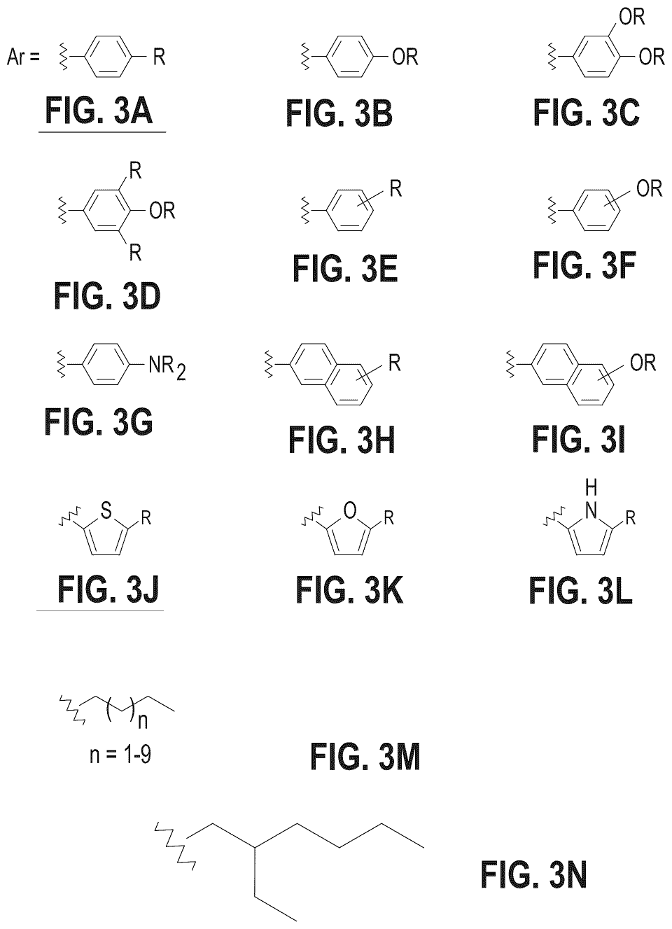

In at least one example embodiment, at least a portion of the GNRs may include edge groups or multiedged or multiple edge groups. As used herein, “edge group” means a purposely and/or consistently substituted elemental or molecular motif at the edge of the GNR. In at least one example embodiment, at least a portion of the GNRs have one or more edge groups including hydrogen, a halogen, an alkyl chain, or a thiophene chain, or a combination thereof. In at least one example embodiment, an edge group is or includes R, where R=H, CH₃, CH₃CH₃, CH₂CH₂CH₃, CH(CH₃)₂, C(CH₃)₃, or any combination thereof. In at least one example embodiment, an edge group is represented by Ar. Examples Ar groups are illustrated in FIGS. 3A-3N. In at least one example embodiment, a GNR includes multiple different types of edge groups. In at least on example embodiment, the GNR is free of edge groups except for H (e.g., R=H).

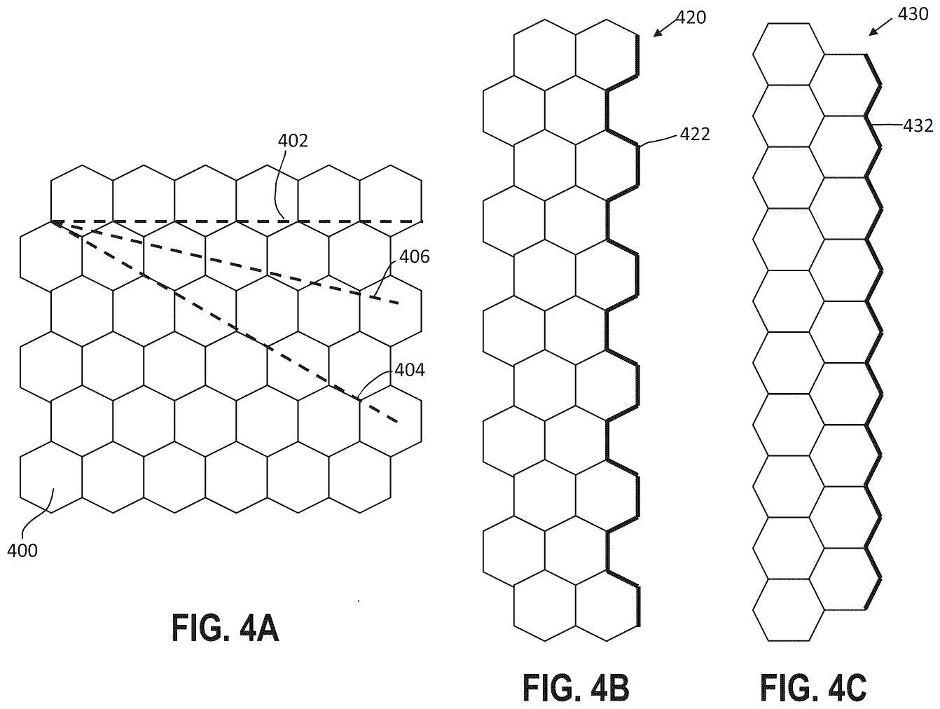

In at least one example embodiment, GNRs include armchair (n, n)-type GMRs, zigzag (n, 0)-type GNRs, in-between (n, m)-type GNRs, cove GNR, or any combination thereof, where n and m are any integer. FIG. 4A is a schematic illustration showing GNR types. Graphene is illustrated at 400. The line 402 illustrates the edge of zigzag (n, 0)-type GNRs. The line 404 illustrates the edge of armchair (n, n)-type GMRs. in-between (n, m)-type GNRs may be between zigzag and armchair. The line 406 illustrates an example edge of in-between (n, m)-type GNRs. n and m are integers. In at least one example embodiment, as shown in FIG. 4B, at least a portion of the GNRs in the active layer 106 (shown in FIG. 1) include armchair GNRs 420 having a long edge as defined at 422. In at least one example embodiment, as shown in FIG. 4C, at least a portion of the GNRs in the active layer 106 include zigzag GNRs 430 having a long edge as defined at 432. In at least one example embodiment, the GNR is a curved GNR.

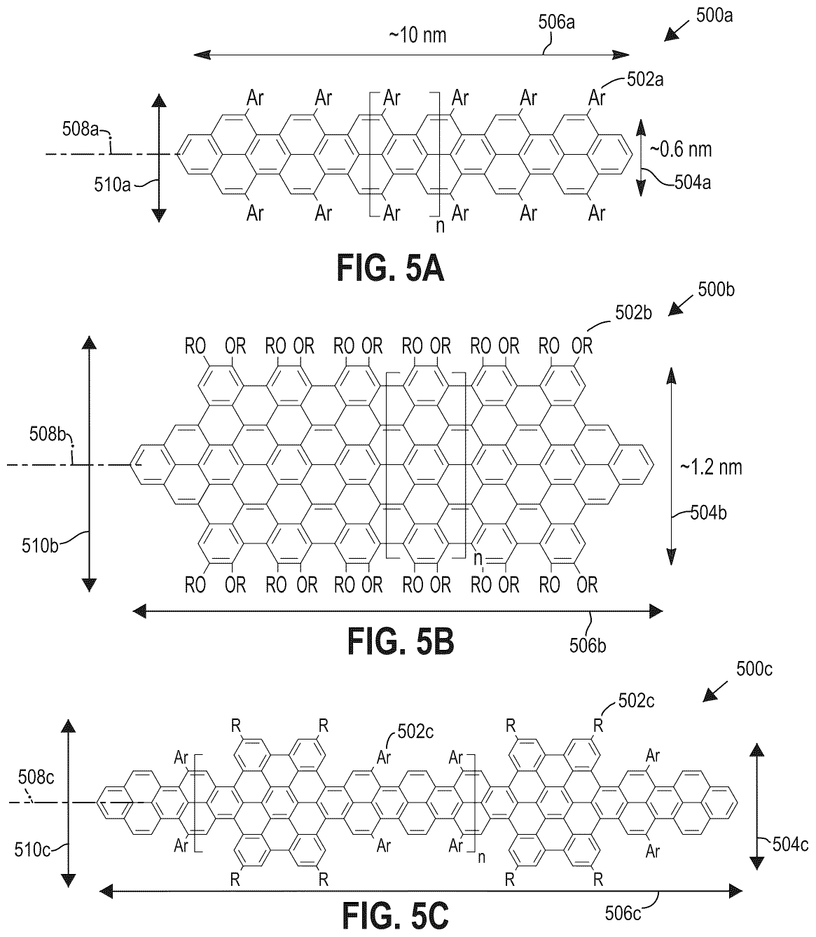

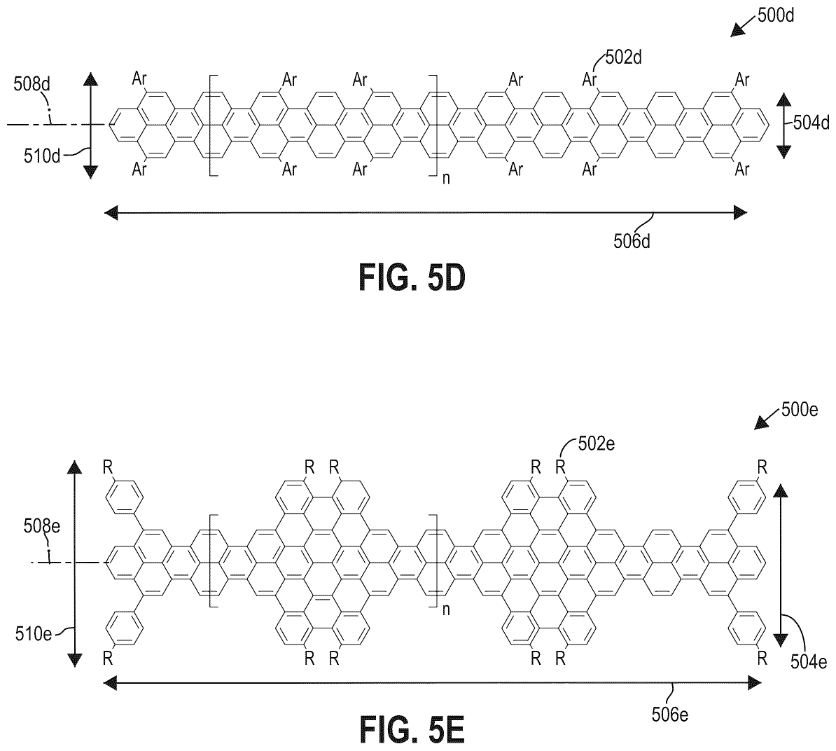

FIGS. 5A-5E illustrate example GNRs in accordance with example embodiments, as described in greater detail below.

As shown in FIG. 5A, a GNR 500a in accordance with at least one example embodiment includes Ar edge groups 502a, where Ar can be any of the groups shown in FIGS. 3A-3N and R=H, CH₃, CH₃CH₃, CH₂CH₂CH₃, CH(CH₃)₂, C(CH₃)₃, or any combination thereof. The GNR 500a has a core width 504a of about 0.6 nm. The GNR 500a has a length 506a of about 10 nm and extends along a longitudinal axis 508a. The GNR 500a has a widest width of 510a.

As shown in FIG. 5B, a GNR 500b in accordance with at least one example embodiment includes OR edge groups, where O is oxygen and R=H, CH₃, CH₃CH₃, CH₂CH₂CH₃, CH(CH₃)₂, C(CH₃)₃, or any combination thereof. The GNR 500b has a core width 504a of about 1.2 nm. The GNR 500b has a length 506b and extends along a longitudinal axis 508b. The GNR 500b has a widest width of 510b.

As shown in FIG. 5C, a GNR 500c in accordance with at least one example embodiment includes R edge groups and Ar edge groups 502b, where R=H, CH₃, CH₃CH₃, CH₂CH₂CH₃, CH(CH₃)₂, C(CH₃)₃, or any combination thereof and Ar can be any of the groups shown in FIGS. 3A-3N. The GNR 500c has a core width 504c, a length 506c, and extends along a longitudinal axis 508c. The GNR 500c has a widest width of 510c.

As shown in FIG. 5D, a GNR 500d in accordance with at least one example embodiment includes Ar edge groups 502d, where Ar can be any of the groups shown in FIGS. 3A-3N and R=H, CH₃, CH₃CH₃, CH₂CH₂CH₃, CH(CH₃)₂, C(CH₃)₃, or any combination thereof. The GNR 500d has a core width 504c, a length 506d, and extends along a longitudinal axis 508d. The GNR 500d has a widest width of 510d.

As shown in FIG. 5E, a GNR 500e in accordance with at least one example embodiment includes R edge groups 502e, where R=H, CH₃, CH₃CH₃, CH₂CH₂CH₃, CH(CH₃)₂, C(CH₃)₃, or any combination thereof. The GNR 500e has a core width 504e, a length 506e, and extends along a longitudinal axis 508e. The GNR 500d has a widest width of 510e.

As used herein, “external quantum efficiency” (EQE) is the efficiency of converting photons of a particular wavelength to electrons. In at least one example embodiment, EQE of the GNRs is greater than or equal to about 0.1% (e.g., greater than or equal to about 0.5%, greater than or equal to about 1%, greater than or equal to about 2%, greater than or equal to about 3%, greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 20%, greater than or equal to about 50%, or greater than or equal to about 80%).

In at least one example embodiment, EQE of the active layer containing the GNRs is greater than or equal to about 0.1% (e.g., greater than or equal to about 0.5%, greater than or equal to about 1%, greater than or equal to about 2%, greater than or equal to about 3%, greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 20%, greater than or equal to about 50%, or greater than or equal to about 80%).

In at least one example embodiment, the GNRs may have a bandgap of greater than or equal to about 0.1 eV (e.g., greater than or equal to about 0.2 eV or greater than or equal to about 0.3 eV). The bandgap may be less than or equal to about 2.5 eV (e.g., less than or equal to about 2 eV, less than or equal to about 1.5 eV, less than or equal to about 1.4 eV, less than or equal to about 1.3 eV, less than or equal to about 1.2 eV, less than or equal to about 1.1 eV, less than or equal to about 1 eV, less than or equal to about 0.9 eV, less than or equal to about 0.8 eV, less than or equal to about 0.7 eV, less than or equal to about 0.6 eV, or less than or equal to about 0.4 eV).

In at least one example embodiment, the GNRs may have a mobility of greater than 1 cm²/V-s, (e.g., greater than 10 cm²/V-s, greater than 50 cm²/V-s, greater than 100 cm²/V-s, greater than 500 cm²/V-s, or greater than 1000 cm²/V-s).

In at least one example embodiment, the GNRs may have a solubility of greater than 0.1 mg/mL (e.g., greater than 0.5 mg/mL, greater than 1 mg/mL, greater than 5 mg/mL, greater than 10 mg/mL, greater than 20 mg/mL, or greater than 50 mg/mL).

In at least one example embodiment, the PV device 100 has an open circuit voltage (V_{OC}) within 75% of the excitonic Shockley-Quisser limit (e.g., within 50% of the excitonic SQ limit, within 20% of the excitonic SQ limit, or within 10% of the excitonic SQ limit), as defined in Lunt et al., “Practical Roadmap and Limits to Nanostructured Photovoltaics” (Perspective) Adv. Mat. 23, 5712-5727, 2011, which is incorporated herein by reference. In at least one example embodiment, the device has an open circuit voltage (V_{OC}) greater than or equal to 0.1V (e.g., greater than or equal to 0.15V or greater than or equal to 0.2V).

In at least one example embodiment, a method of preparing a PV device including GNRs includes synthesizing GNRs. The method may further include adding the GNRs to a photoactive layer and/or incorporating the GNRs into a PV device. Synthesizing the GNRs may include synthesis from the ground up. Active layers may be coated on substrates and/or electrodes using spin-coating, spray coating, slot-die coating, web coating, curtain coating, vacuum deposition, or any combination thereof. The GNRs may be synthesized in-situ on the device substrate in different orientations.

### Example

In at least one example embodiment, PV devices utilizing GNRs as a photoactive component are demonstrated. GNRs function as electron donors when paired with fullerene (C₆₀) in bilayer graphitic devices and generate photocurrent across the solar spectrum to their bandgap. Optical modeling is used to dissect device performance into individual components and identify charge transport and carrier mobility limitations stemming from out-of-plane resistance from bulk GNR films. In presenting GNR photoactive devices a new window is opened for the utilization of graphitic materials in renewable energy technologies.

Results.

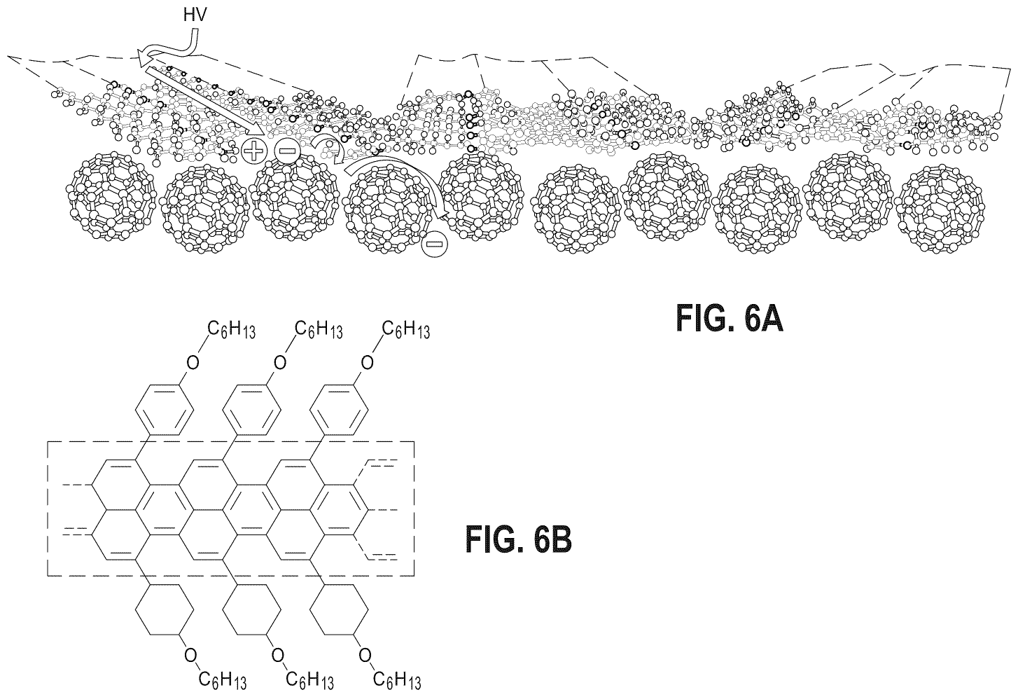

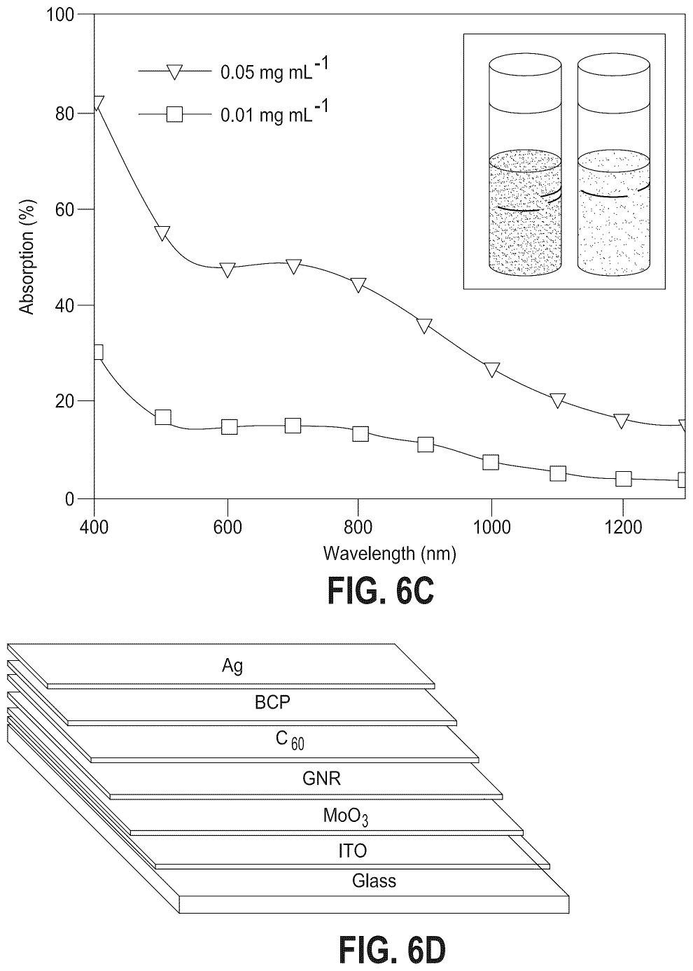

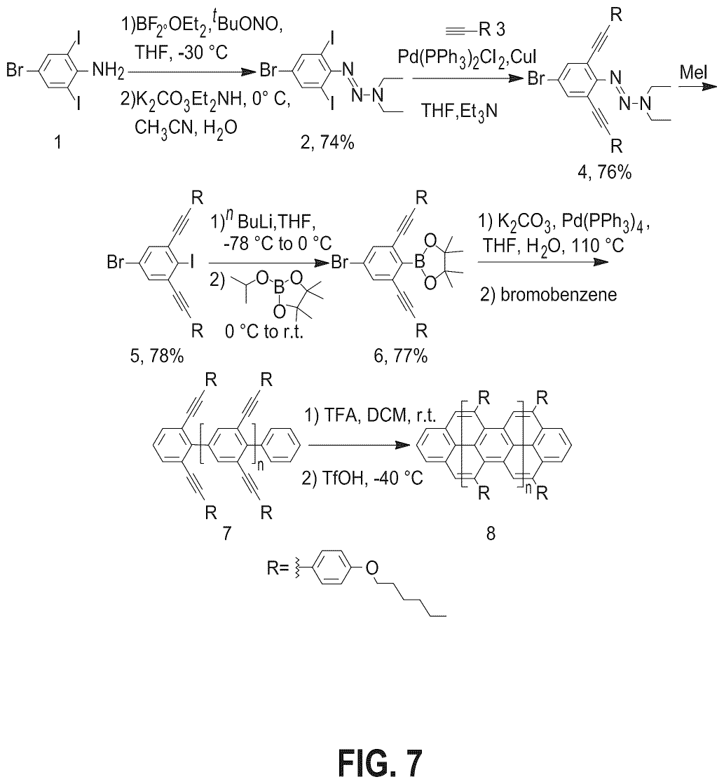

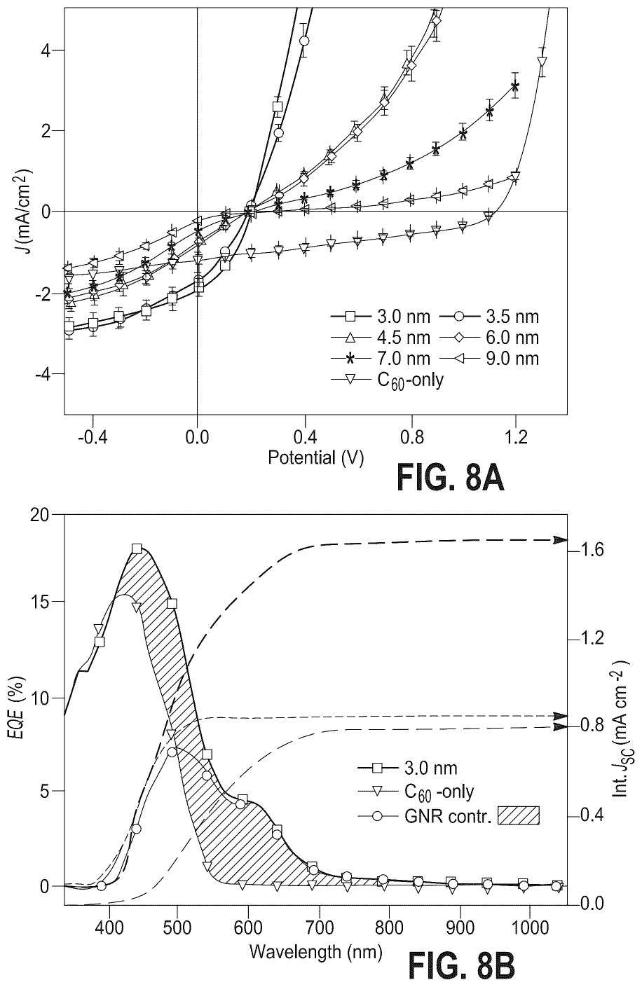

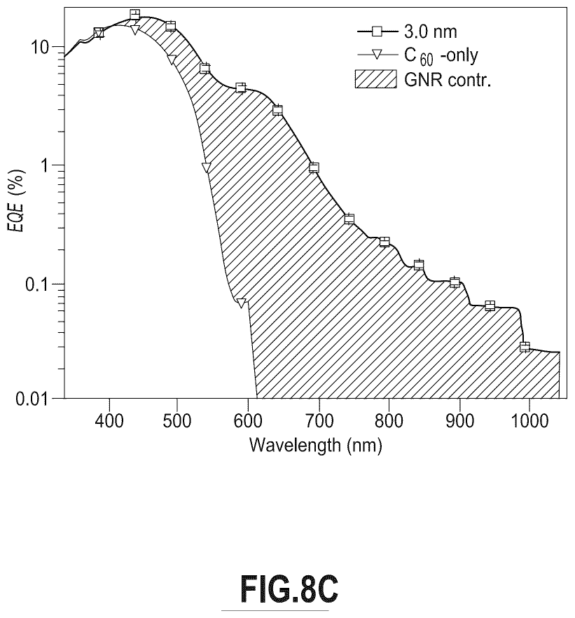

Demonstration of photocurrent from GNRs: Bilayer solar cells with an active layer comprised of GNR (donor) and C₆₀ (acceptor) are fabricated to explore the photovoltaic effect of GNRs. A representation of GNR generated photoelectrons in the active layer is shown in FIG. 6A, where GNRs absorb light to generate excitons, which diffuse to the donor-acceptor interface and separate so that GNR photoelectrons are transferred through the fullerene layer. Carbon is shown at 600 (lightest weight lines), hydrogen is shown at 602 (medium weight lines), and oxygen is shown at 604 (heaviest weight lines). The GNRs shown schematically in FIG. 6B are synthesized using nonoxidative alkyne benzannulation, shown in FIG. 7. They exhibit a bandgap of approximately 1.03 eV, harvesting photons across the UV, VIS, and NIR portions of the solar spectrum. Solution absorption profiles of the GNR at 0.01 mg mL⁻¹ and 0.05 mg mL⁻¹ are shown in FIG. 6C. At high concentrations, the GNR exhibits strong aggregation effects, resulting in scattering deep into the NIR spectrum. The current-voltage (J-V) characteristic curves of PVs with a bilayer architecture (FIG. 6D) are measured with varying GNR (here, donor layer thickness) thicknesses (FIG. 8A). This data is compared to a C₆₀-only (Shockley diode) device for reference. The first and most obvious feature is the reduction in the open circuit voltage (V_{OC}) when the GNRs are added to the device. This is expected as the GNR bandgap is much smaller than that of the C₆₀. The short circuit photocurrent density (J_{SC}) increases with the GNR layer present at 3.0 and 3.5 nm thicknesses, indicating GNR photocurrent contributions. External quantum efficiencies (EQE) are measured, and the 3.0 nm device is shown in comparison to the C₆₀-only device in FIG. 8B. The GNR clearly contributes photocurrent to the device in the UV, VIS, and NIR regions, marking an important demonstration of GNRs as a functional active material in PVs. While C₆₀ absorbs only into the middle of the visible region, the devices produce current to past 1000 nm into the NIR (FIG. 8C). Actual current contribution of the GNR is estimated as the difference between the 3 nm and C₆₀-only devices, shown as the black line in FIG. 8B. Peak EQE from the GNR is greater than 6% at 500 nm, demonstrating improved performance compared to the 2.3% EQE achieved by CNTs in their first photoactive optoelectronic demonstration. EQE can be integrated with Eq. 1 to calculate the J_{SC}, where S is the AM1.5G solar spectrum in photon flux and q is the elementary charge.

J_{SC}=q∫EQE(λ)S(λ)dX Eq. 1

The estimated GNR contribution to the integrated J_{SC} is roughly half of the total device photocurrent at 3.0 nm GNR, highlighting the broad-spectrum absorption due to the low bandgap.

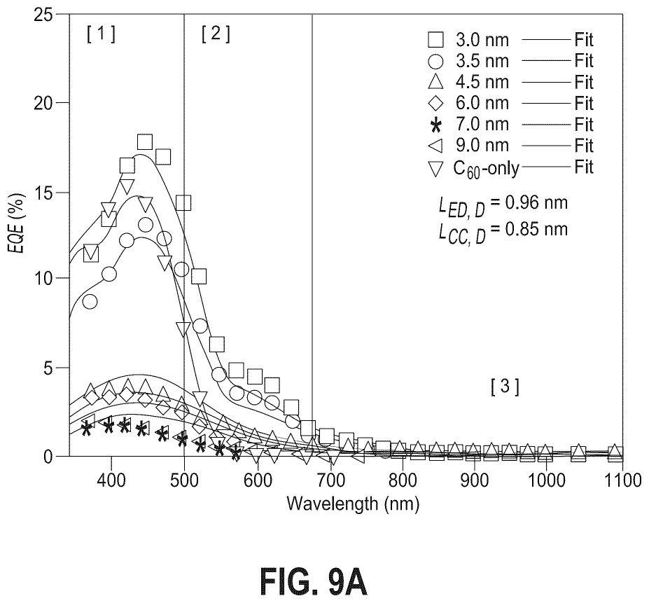

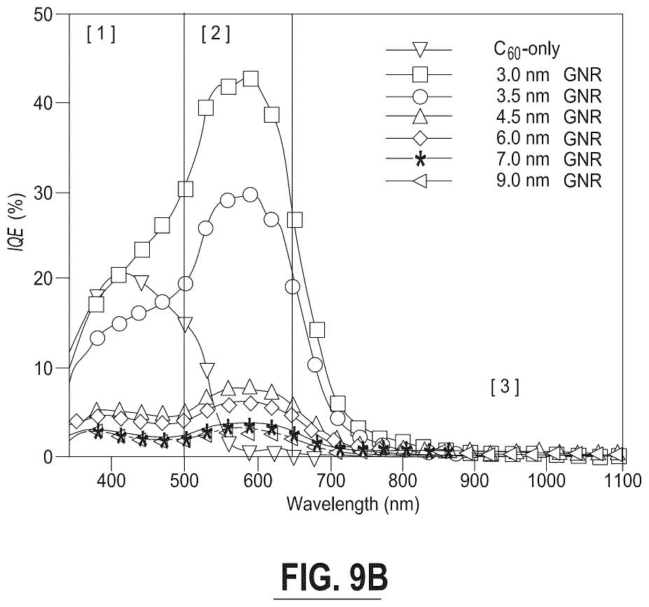

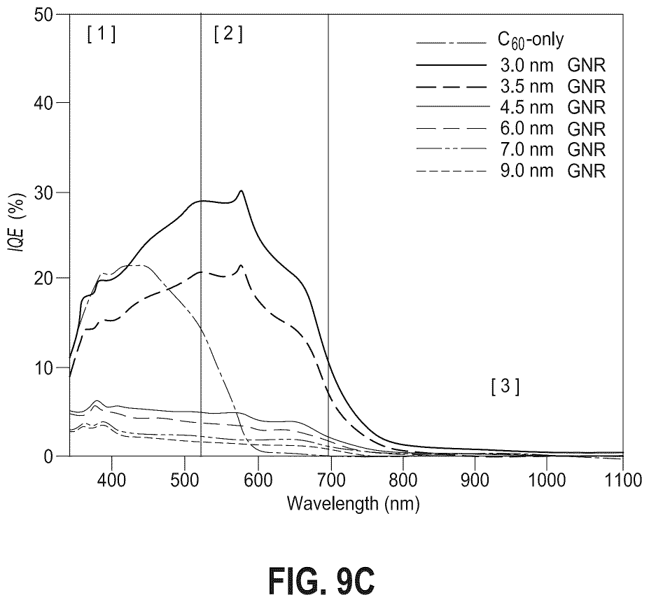

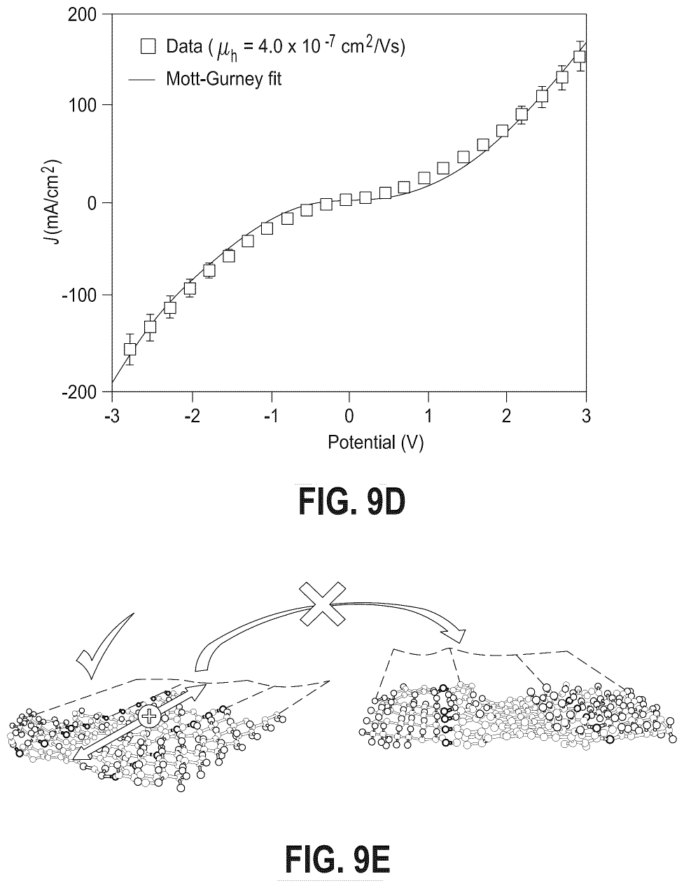

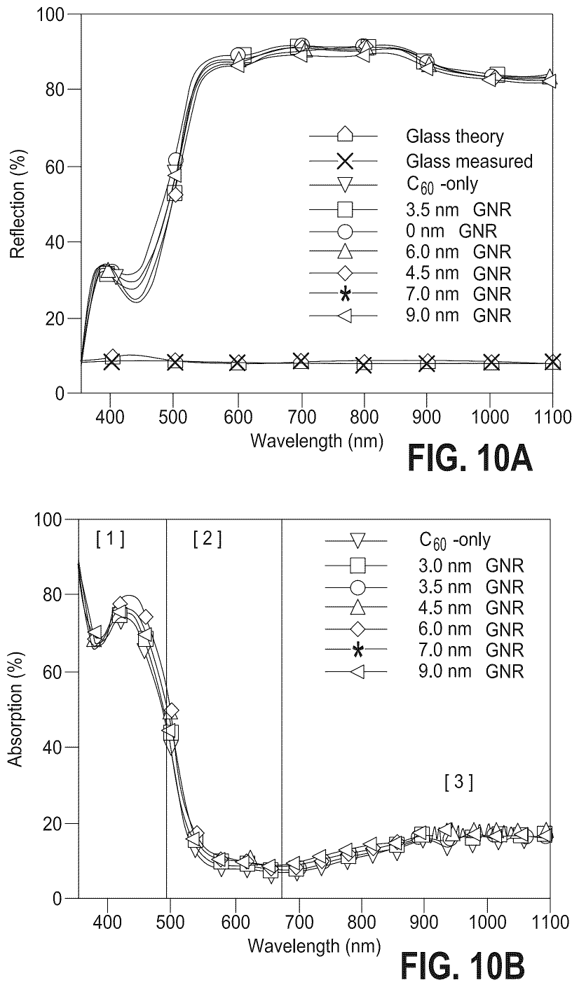

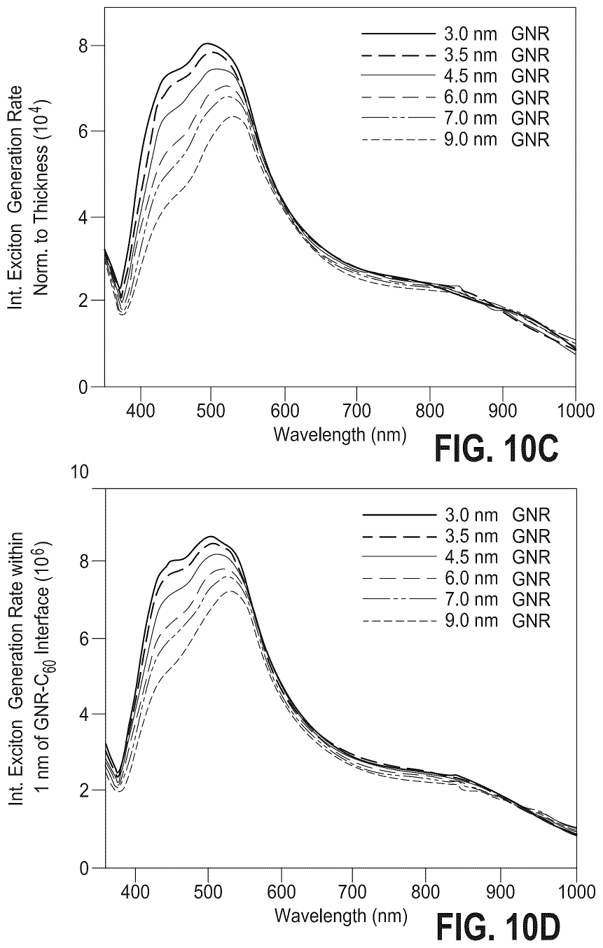

Analysis of EQE trends: To understand the capabilities and limitations of GNR as a photoactive material lying in a flat configuration, GNR thickness dependent EQE (FIG. 9A) is studied, which shows three distinct regions for thin films of GNR (3.0 and 3.5 nm). Region 1 consists of the UV and short VIS, where C₆₀ produces a large portion of the photocurrent and dominates the absorption profile relative to GNR (FIG. 10B). In region two, C₆₀ absorption quickly falls off, leaving GNR as the primary contributor to the photocurrent seen in the EQE shoulder out to 650 nm for 3.0 and 3.5 nm GNR that is absent from the C₆₀-only device. GNR absorption is relatively flat across the UV, VIS, and NIR, however the EQE decreases in region 3 to less than 1% at 700 nm. Importantly, as the GNR thickness increases beyond 3.5 nm, EQE from the C₆₀ is greatly diminished to well below the C₆₀-only device EQE. This effect is also observed in the thickness dependent J-V curves in both the forward slope (inversely proportional to the resistance) and the J_{SC} with increased GNR thickness, corroborating the observed EQE trends through Eq. 1. EQE can be understood as the product of five component efficiencies (Eq. 2) for absorption (η_{A}), exciton diffusion (η_{ED}), charge transfer (η_{CT}), charge dissociation (η_{DS}), and charge collection (η_{CC}).

EQE=η_{A}η_{ED}η_{CT}η_{DS}η_{CC} Eq. 2

The C₆₀-GNR junction is formed in the same manner for all GNR thicknesses and yields a thickness independent V_{OC}, indicative of reduced or minimal band bending and a consistent interface gap between the highest occupied molecular orbital (HOMO) of the GNR and the lowest unoccupied molecular orbital (LUMO) of the C₆₀. Given a stable GNR bandgap, the LUMO-LUMO offset that controls exciton dissociation into free charge carriers will be consistent such that ηCT and ηDS are independent of GNR thickness. As the C₆₀ thickness is constant, this leaves absorption, exciton diffusion, and charge collection losses in the GNR as remaining factors to explain the decrease in EQE across the spectrum. To examine the EQE trends independent of GNR and C₆₀ absorption, the internal quantum efficiency (IQE) is calculated (FIG. 9B) from Eq. 3 using the experimentally measured EQE and absorption.

$$IQE = \frac{EQE}{{η}_{A}} = {η}_{ED} {η}_{CT} {η}_{DS} {η}_{CC} \qquad Eq . 3$$

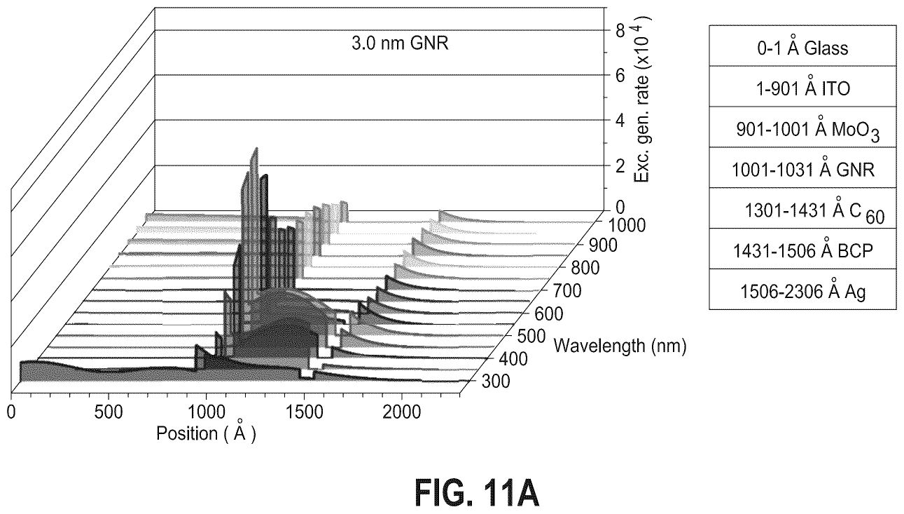

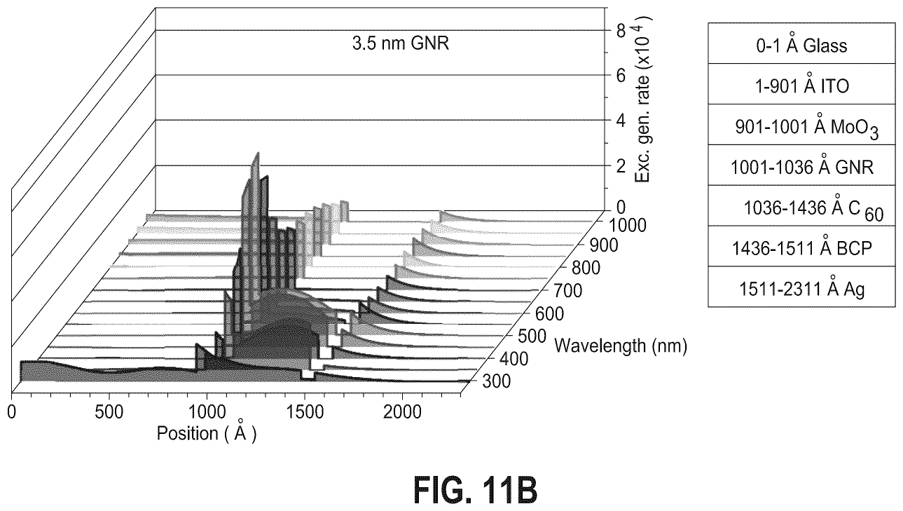

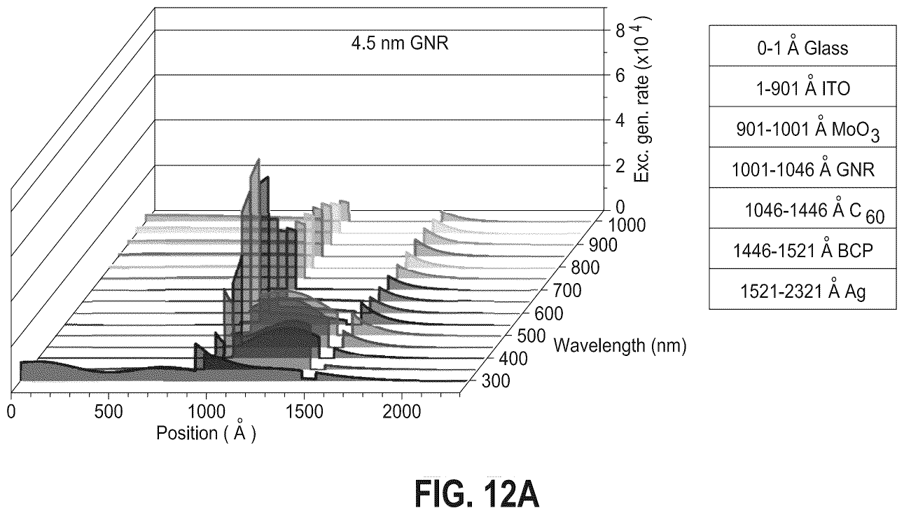

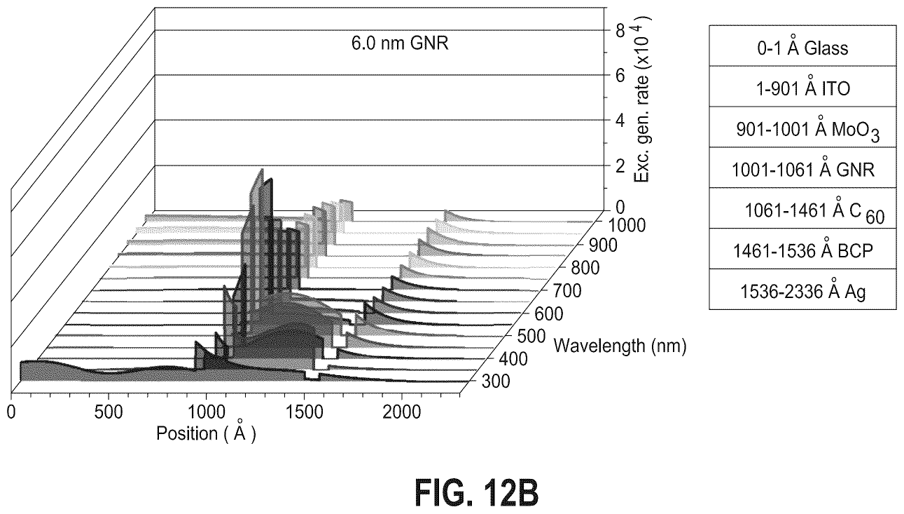

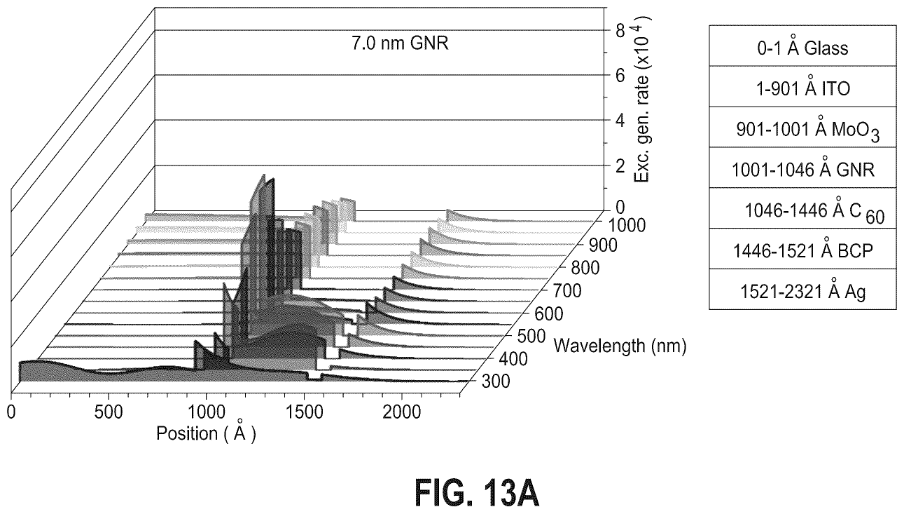

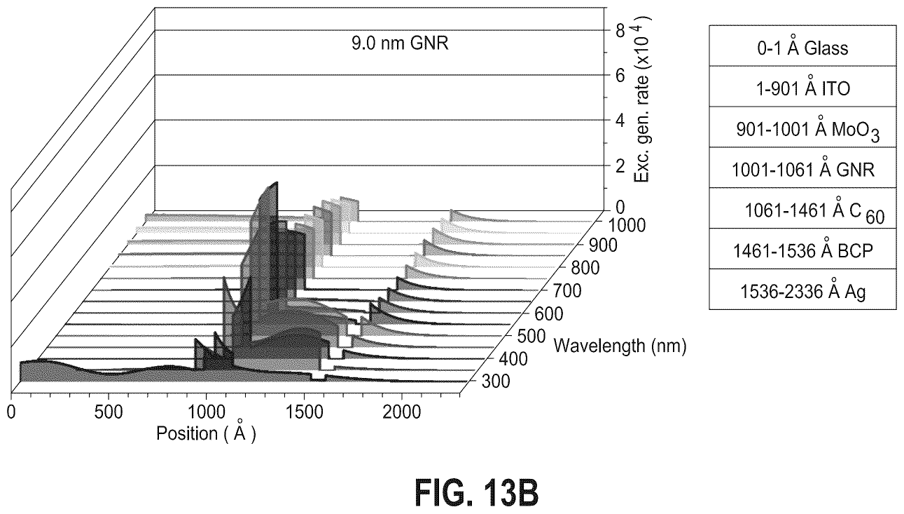

Absorption for the entire device stack is obtained from the measured reflection as 100−reflection (%) (FIG. 10A) and used in place of η_{A}, the absorption efficiency of the active layers. Similar to the EQE, three regions of IQE behavior are observed, particularly for 3.0 and 3.5 nm GNR devices. In region 1, the IQE consists of excitonic and charge carrier processes originating in both the C₆₀ and GNR. While IQE is generally independent of absorption effects, it can vary spectrally in two important ways. The IQE in region 1 is the result of component IQEs from the C₆₀ and GNR depending on the location of photon absorption. Given the much stronger absorption of C₆₀ in this regime (FIG. 8B), the majority of excitons generated are in the C₆₀ layer and thus the resulting overall IQE will be heavily weighted towards the efficiency with which excitons formed in C₆₀ are extracted as free charge carriers. This analysis is validated by the similar IQE of the C₆₀-only and the 3.0 and 3.5 nm GNR devices in region 1. IQE increases rapidly for thin layers of GNR as it moves into region 2 as a result of the reversal of the absorption trend from region 1, where GNR now becomes the primary location for exciton formation. Thin layers of GNR allow for the moderately high IQEs observed in this region and the strong GNR thickness dependence of the IQE in regions 1 and 2 indicates large charge collection limitations that reduce photocurrent from the C₆₀ and GNR. Charge collection and exciton diffusion efficiencies are generally independent of the exciting wavelength, which combined with the relatively flat absorption of GNRs would suggest that the IQE for a given GNR thickness should be consistent to the GNR bandgap. However, the IQE declines into region 3, and in this transition the primary location of exciton formation is still the GNR layer as it was in region 2. The second mechanism for absorption to impact the IQE is through optical interference effects, as the IQE can vary spectrally based on the location of exciton generation at each wavelength. Excitons generated nearer to a dissociating interface are more likely to successfully diffuse to the interface, increasing η_{ED}. Exciton generation rate is a function of the molecular extinction coefficient and the electric field, the latter of which depends in part on the overall device thicknesses. Altering the thickness of an active material can affect the IQE by enhancing exciton generation closer to the donor-acceptor interface for a given wavelength independent of the absorption efficiency. To understand the wavelength dependence of the IQE in region 3, transfer matrix optical modeling is used to calculate the exciton generation rate profiles (FIGS. 11A-13B). Integrating the exciton generation rate across the GNR layer and normalizing to the GNR thickness yields wavelength resolved profiles (FIG. 10C) that show strong exciton generation peaking from 400 nm to 600 nm and then declining consistently to 1000 nm. However, exciton generation rates within 1 nm of the GNR-C₆₀ interface (FIG. 10D) demonstrate the same overall trend, indicating that while there is heightened exciton generation in the VIS region, it does not lead to preferential generation closer to the interface and therefore will not increase η_{ED}. Enhanced exciton generation throughout the layer will impact the EQE, but does not explain the observed IQE behavior in region 3. The IQE behavior can however be explained by the increased parasitic absorption of the ITO electrode in the NIR, which causes the overall absorption to increase in the NIR (FIG. 11B, region 3) and the IQE to steeply decrease. To investigate this explanation, IQE is calculated using the optical model generated absorption and observe comparable IQE in regions 1 through 3 to the experimentally determined IQE, further validating this analysis (FIG. 9C). For thicker GNR layers, the enhancement from favorable exciton generation is overwhelmed by charge collection losses that sharply reduce the IQE and EQE across the spectrum, including from the C₆₀. To understand the extent of the limitations imposed by exciton diffusion and charge collection, transfer matrix optical modeling is paired with a nonlinear regression analysis to simultaneously fit the GNR thickness dependent EQE for the exciton diffusion length, L_{ED,D}, and charge collection length, L_{CC,D}, of the GNR. The processes quantified by this model are specifically for exciton diffusion and charge collection occurring vertically through a bulk film of GNRs, and normal to a horizontally or near-horizontally oriented ribbon. Equations for each process are given in Eq. 4 and Eq. 5, where d is the GNR thickness.

$$\begin{matrix}{η}_{ED} = exp ( \frac{- d}{{L}_{ED}} ) & Eq . 4 \\ {η}_{CC} = ( \frac{{L}_{CC}}{d} ) ( 1 - exp ( \frac{- d}{{L}_{CC}} ) ) & Eq . 5\end{matrix}$$

The resulting fit is shown in FIG. 9A, where the overall EQE decay trend with GNR thickness is well matched by the model. Extracted characteristic lengths of 0.96 nm and 0.85 nm for L_{ED,D} and L_{CC,D} confirm the previous conclusions about the limitations in horizontally oriented GNR PVs and highlight charge collection and exciton diffusion as the important areas for improvement with these materials that would likely (and largely) be overcome with vertical alignment. Importantly, while L_{ED,D} will limit current produced by the GNR, L_{CC,D} limits photocurrent production from both the GNR and C₆₀, making charge collection the limiting factor for horizontally aligned GNR-based photovoltaic performance in this example. Given that a very large degree of anisotropy is expected, vertically oriented GNRs should show increased exciton diffusion and charge collection lengths, which may be significantly increased exciton diffusion and charge collection lengths.

Hole transport in GNRs: To further understand the cause of charge collection losses in GNR based PVs, hole-only devices are fabricated on ITO coated glass substrates with a 20 nm GNR layer sandwiched between two 50 nm MoO₃ layers and capped with an 80 nm Ag top electrode. J-V curves are measured in the dark and fit with the Mott-Gurney equation for space charge limited current after confirming J-V symmetry (no diode formation or built-in bias) between forward and reverse bias (FIG. 9D). A hole mobility of 4.0±0.3·10⁻⁷ cm²V⁻¹s⁻¹ was extracted from the fitted data, further evidence of charge collection limitations seen in the EQE thickness dependent data. Given the nature of GNRs and other graphene-derived materials, the mobility is notably low. However, this is a measurement of a bulk film of GNRs with transport primarily occurring through stacks of nanoribbons (consistent with the PV device architecture) as opposed to the mobility in-plane of the GNR. The low mobility indicates that hole transport from ribbon to ribbon is not very efficient (FIG. 9E), while the intra-ribbon transport is still likely to be very high. It is estimated that GNR thickness variation from 3.0 nm to 9.0 nm increases the average number of ribbons stacked in the layer from 9 to 27, assuming well aligned GNRs and a graphite layer separation of 0.335 nm. From this it is concluded that inter-ribbon transport is moderately efficient between fewer than 10 ribbons. Holes traveling between more ribbons face a higher chance of recombination and thus provide lower photocurrent across the solar spectrum. Poor inter-ribbon carrier mobility supports previous conclusions from EQE analysis that devices are limited by charge collection losses reducing the photocurrent from both C₆₀ and GNRs.

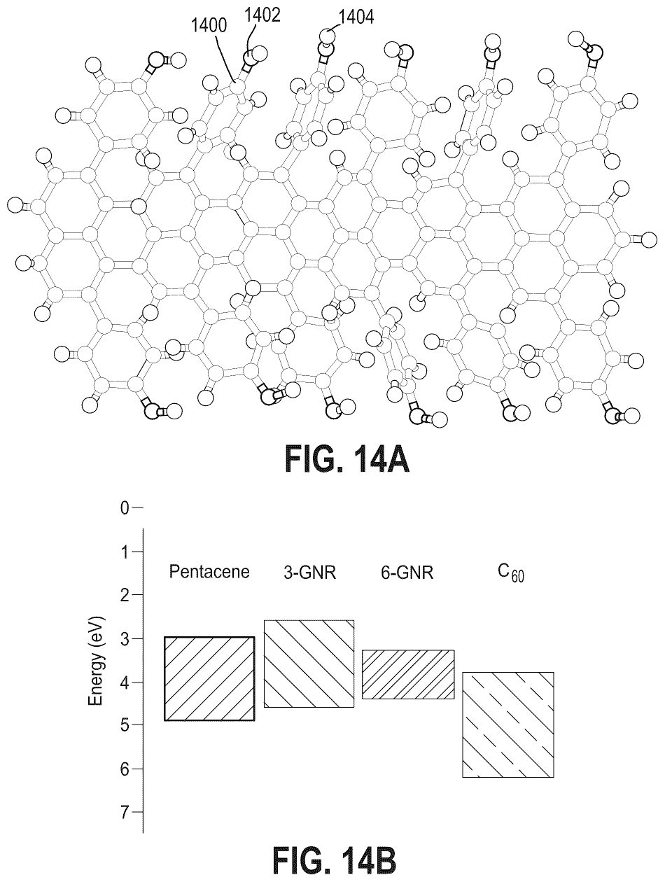

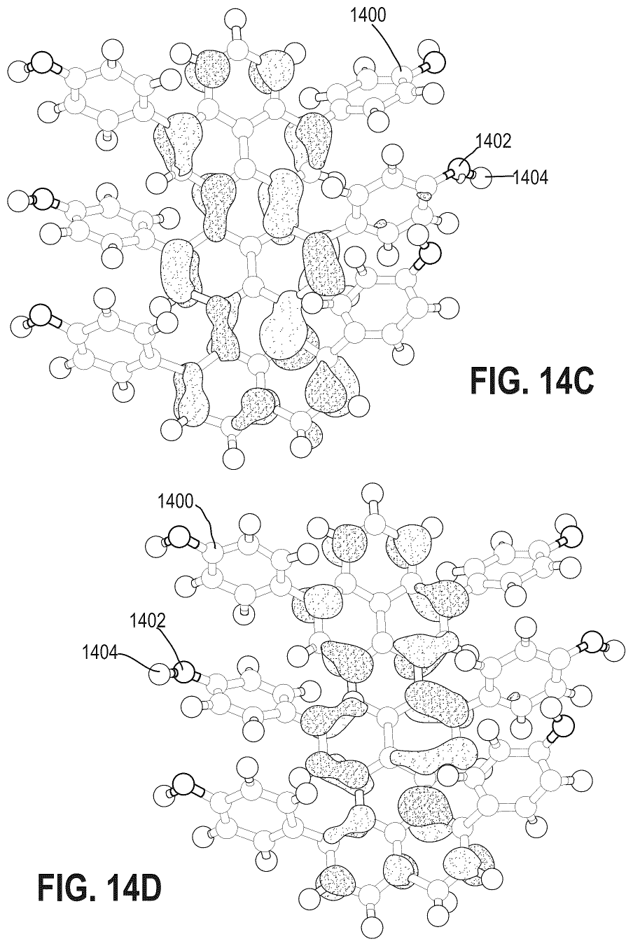

Calculation of the GNR bandgap: The bandgap and frontier molecular orbital energy levels are calculated for GNRs consisting of 3 (3-GNR) and 6 (6-GNR, shown in FIG. 14A, where carbon is shown at 1400 or lightest weight lines, oxygen is shown at 1402 or heaviest weight lines, and hydrogen is shown at 1406 or lightest weight lines) repeating units due to the large computational cost of the full GNR (˜23 repeating units). The extension of the conjugated network from 3-GNR to 6-GNR narrows the bandgap, and after adjusting based on the pentacene control, results in a reasonable estimate for the 6-GNR electronic bandgap of 1.1 eV with a HOMO level at ˜4.4 eV relative to vacuum. Our calculated bandgap aligns well with the optical bandgap of 1.03 eV and the EQE cutoff, which shows photocurrent generation up to 1050 nm (˜1.18 eV). Corrected orbital levels are shown in FIG. 14B with the levels of C₆₀. The interface gap between the 6-GNR HOMO and C₆₀ LUMO is approximately 0.6 eV, yielding an expected voltage of 0.35 V from the SQ limit. The measured V_{OC} of the GNR-C₆₀ device (0.2 V) sits 0.15 V below the SQ limit and suggests a loss of 0.4 eV from the optical excitonic bandgap. Calculated HOMO and LUMO for 3-GNR are shown in FIGS. 9C-9D, displaying the conjugated network at the core of the GNR.

### DISCUSSION

Graphene and nanostructured graphene derivatives make up an important class of emerging electronic and optoelectronic materials. This example embodiment demonstrates graphene-based photovoltaics based on size constrained GNRs. This is achieved by fabricating bilayer all carbon (photoactive layer) solar cells with GNR as a donor and C₆₀ as an acceptor. Complimentary absorption profiles of the active materials allow us to clearly show GNR contributions to the photocurrent at wavelengths from 450 nm to past 1000 nm deep into the NIR. Devices are primarily limited by the large resistance of the GNR films that increased with thickness, evidenced by the decreasing slope of the forward current in J-V, curves and declining EQE across the UV-VIS and NIR wavelengths. This resistance resulted in charge collection losses due to the small charge collection length and hole mobility of bulk GNR films. Increasing the arrangement of the ribbons (vertically as opposed to horizontally) in the film should improve carrier mobility and charge collection lengths dramatically that would then allow for devices with much thicker GNR layers. Indeed, properly oriented, vertically aligned GNRs synthesized in-situ from the electrode could be a route to achieving the necessary conductivity in a bulk GNR film. Moving forward, characterization and control over GNR orientation and the impact on device performance will be an important step to realizing the full potential of nanoscale graphene materials in these optoelectronic devices. To maximize PV performance, the energy level of the acceptor LUMO with respect to the GNR HOMO should also be optimized so as to maximize the V_{OC} while still dissociating excitons at the donor-acceptor interface. As the bandgap size is suitable in existing ribbons, increasing the acceptor LUMO while maintaining a GNR bandgap of ˜1 eV will be an important step and could be explored by varying acceptors, or even modifying the GNR HOMO with variations in electron donating and accepting capabilities of the side chains. At least one example embodiment demonstrates integration of photoactive GNRs into photovoltaic devices and demonstrated light current production from the GNRs across the UV-VIS and NIR spectrums to the bandgap of the GNR. experimental and computational techniques are used to identify an important area necessary to enhance the performance of GNRs in photovoltaics and provide a route forward to take full advantage of this exciting new class of materials.

Materials and Methods.

Synthesis Overview: The synthesis scheme is presented in FIG. 7. All reactions dealing with air- or moisture-sensitive compounds are carried out in a dry reaction vessel under nitrogen. Anhydrous tetrahydrofuran (THF) and dichloromethane (DCM) are obtained by passing the solvent (HPLC grade) through an activated alumina column on a PureSolv MD 5 solvent drying system. ¹H and ¹³C NMR spectra are recorded on Varian 400 MHz or Varian 500 MHz NMR Spectrometers. Spectra are recorded in deuterated chloroform (CDCl₃). Chemical shifts are referenced to the residual protio-solvent peaks (7.26 ppm for ¹H and 77.16 ppm for ¹³C, respectively). Chemical shifts are reported in part per million (ppm) from low to high frequency and referenced to the residual solvent resonance. Coupling constants (J) are reported in Hz. The multiplicity of ¹H signals are indicated as: s=singlet, d=doublet, t=triplet, m=multiplet, and br=broad. High resolution APPI mass spectra are recorded using an Agilent 6230 TOF MS. TLC information was recorded on Silica gel 60 F254 glass plates. Purification of reaction products was carried out by flash chromatography using Silica Gel 60 (230-400 mesh).

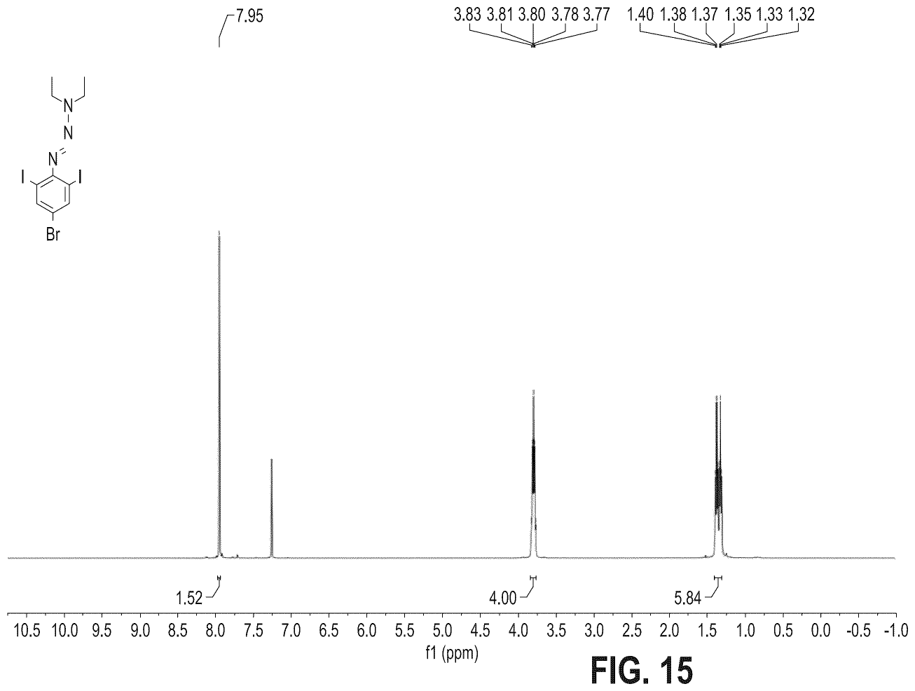

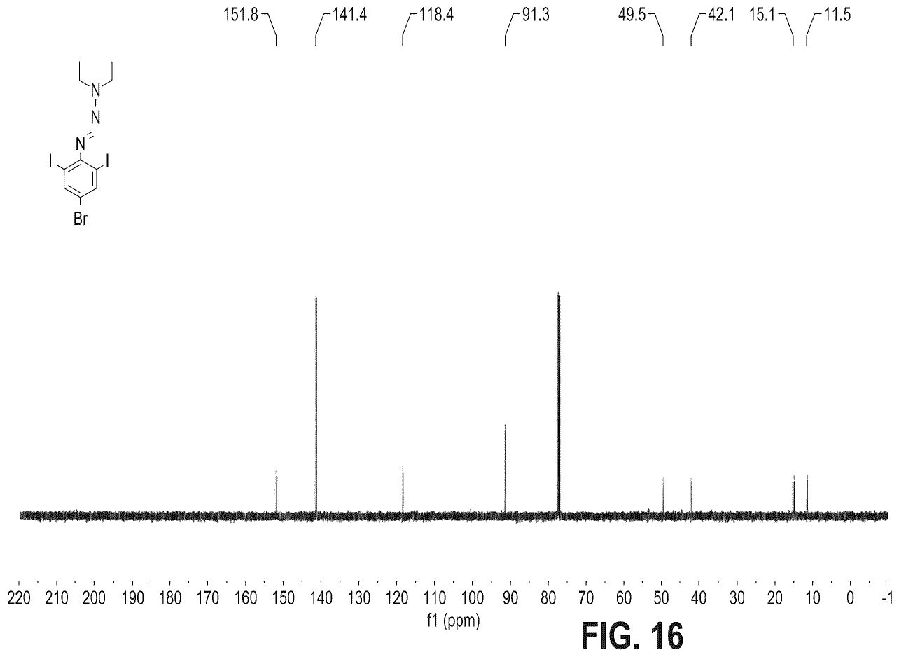

Synthesis of Compound 2: A solution of Compound 1 (FIG. 7) (8.850 g, 20.88 mmol, 1.0 equiv.) in 190 mL THF was cooled to −30° C. and BF₃·OEt₂ (11.339 g, 79.895 mmol, 3.8 equiv.) was added dropwise over 10 minutes. The reaction was stirred at −30° C. for 15 minutes and ^{t}BuONO (7.543 g, 73.14 mmol, 3.5 equiv.) was added dropwise over 10 minutes at −30° C. The reaction was allowed to warm to room temperature and stir for 2 hours. Yellow diazonium salts formed and the solution was further triturated with 60 mL diethyl ether. The salts are filtered from the red solution and rinsed with diethyl ether. The salts are redissolved with 150 mL acetonitrile and cooled to 0° C. A solution of K₂CO₃ (7.509 g, 54.33 mmol 2.6 equiv.) and Et₂NH (3.049 g, 41.69 mmol, 2.0 equiv.) in 40 mL water was added slowly over 5 minutes at 0° C. The solution was allowed to slowly warm to room temperature and stirred for 3 hours. 100 mL of water was added and the layers are separated. The organic layer was washed with brine, dried over anhydrous Na₂SO₄, filtered, and the solvent was removed under reduced pressure. The crude product was purified by flash column chromatography (silica gel, 2:1 hexane:DCM) to yield pure Compound 2 as an orange oil (7.834 g, 74%). Rt=0.60 (1:1 hexane:DCM). FTIR (neat) 2972, 2930, 1546, 1464 cm⁻¹. ¹H NMR (500 MHz, CDCl₃) δ 7.95 (s, 1H), 3.80 (m, 4H), 1.36 (m, 6H) ppm (FIG. 15). ¹³C NMR (126 MHz, CDCl₃) b 151.8, 141.4, 118.4, 91.3, 49.5, 42.1, 15.1, 11.5 ppm (FIG. 16). HRMS (APPI) m/z calculated [C₁₀H₁₂Br₁₂N₃]⁺ 506.8299; found 506.8321.

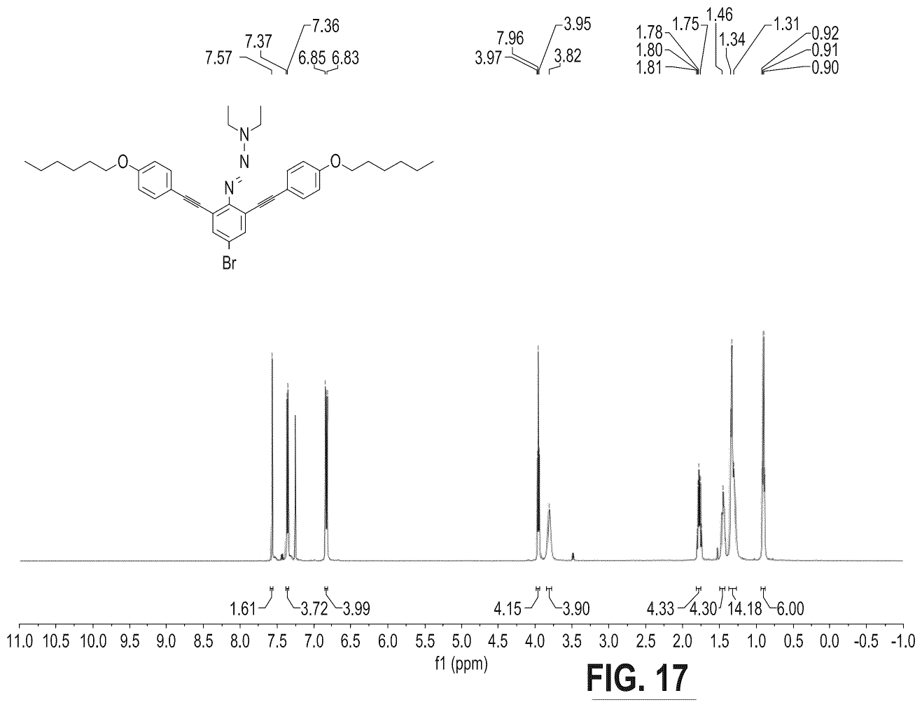

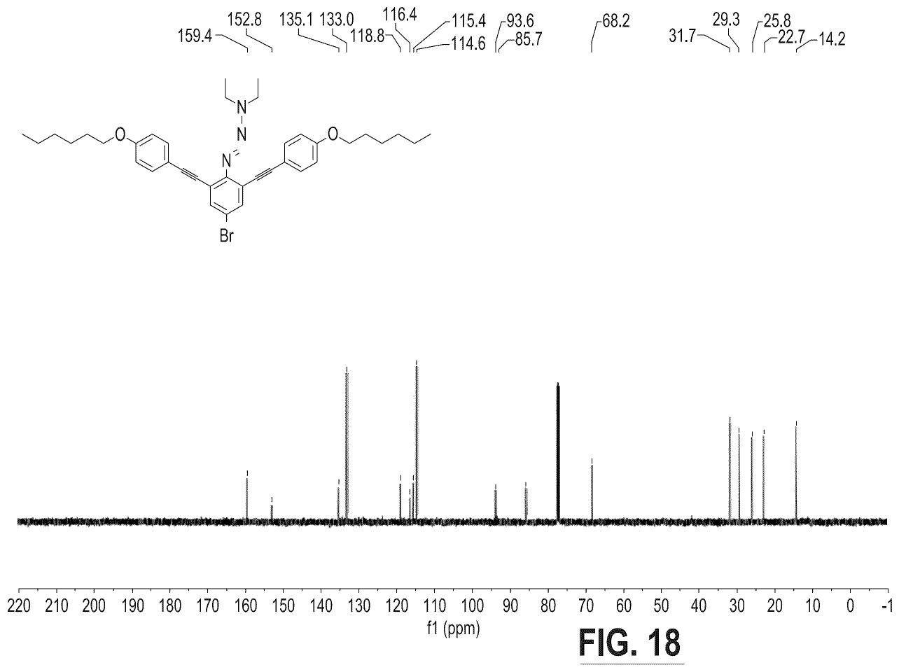

Synthesis of Compound 4: A solution of 2 (7.0749 g, 13.929 mmol, 1.0 equiv.) and 3 (7.0689 g, 34.943 mmol, 2.5 equiv.) in 80 mL THF and 20 mL Et₃N was deoxygenated by bubbling nitrogen gas through the solution for 10 minutes. Pd(PPh₃)₂Cl₂ (196 mg, 0.279 mmol, 0.02 equiv.) was added. Nitrogen was bubbled for 2 minutes, CuI (106 mg, 0.557 mmol, 0.04 equiv.) was added, and nitrogen was bubbled for another 8 minutes. The solution was left to stir for 18 hours under an atmosphere of nitrogen. Amine salts are removed by filtration and solvent was removed under reduced pressure. Catalyst was removed by passing the crude mixture through a plug of silica gel with DCM. Hexane was used to precipitate solids, and the solids are recrystallized in methanol to yield pure Compound 4 (also referred to as “Triazene 4″) as a yellow solid (6.909 g, 76%). It is noted that Compound 4 appears to degrade on silica gel, therefore column chromatography was not used for purification. R_{f}=0.26 (3:1 hexane:DCM). FTIR (neat) 2937, 2865, 2205, 1604, 1552 1507 cm⁻¹. ¹H NMR (500 MHz, CDCl₃) δ 7.57 (s, 2H), 7.36 (d, J=8.6 Hz, 4H), 6.84 (d, J=8.7 Hz, 4H), 3.96 (t, J=6.6 Hz, 4H), 3.85-3.77 (m, 4H), 1.82-1.74 (m, 4H), 1.50-1.42 (m, 4H), 1.39-1.25 (m, 14H), 0.94-0.87 (m, 6H) ppm (FIG. 17). ¹³C NMR (126 MHz, CDCl₃) b 159.4, 152.8, 135.1, 133.0, 118.8, 116.4, 115.4, 114.6, 93.6, 85.7, 68.2, 31.7, 29.3, 25.8, 22.7, 14.2 ppm (FIG. 18). HRMS (APPI) m/z calculated [C₃₈H₄₆BrN₃O₂]⁺ 655.2768; found 655.2767.

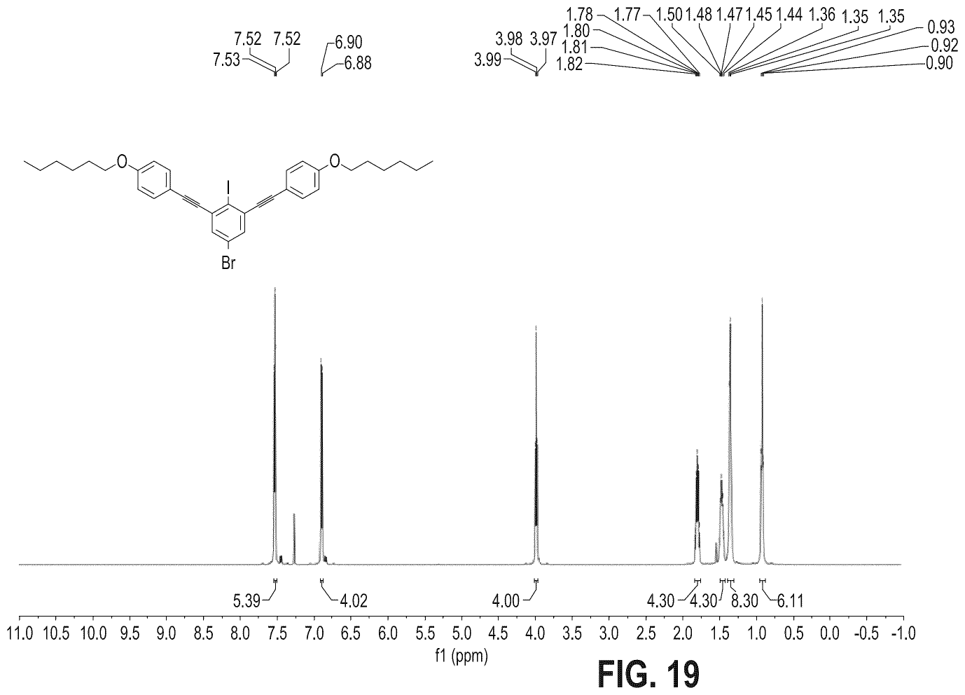

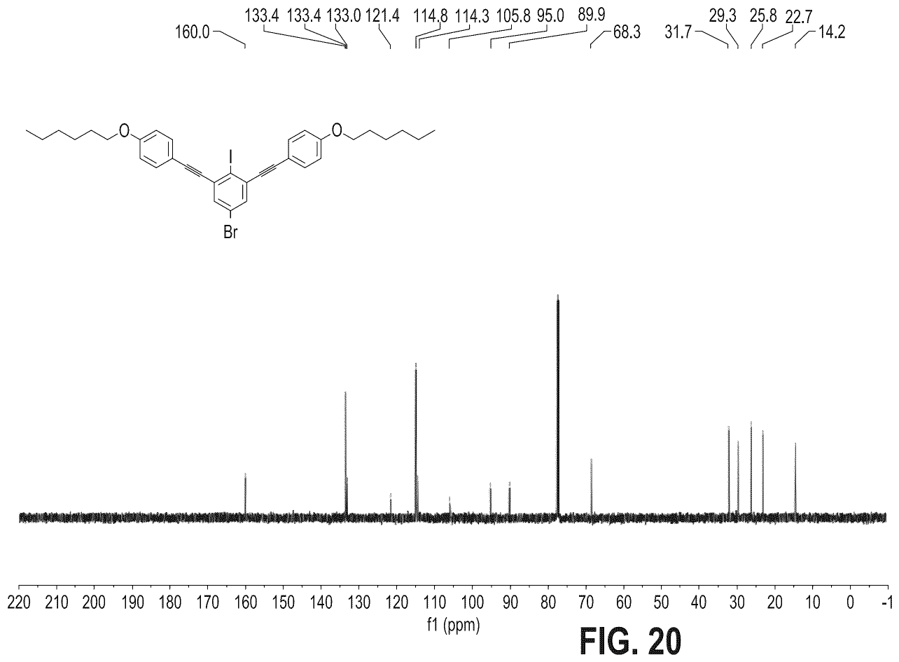

Synthesis of Compound 5: Triazene 4 (3.000 g, 4.568 mmol) was dissolved in excess iodomethane (50 mL) and the solution was heated in a sealed, thick-walled flask at 130° C. for 18 hours. The reaction mixture was cooled, and the solvent was removed under reduced pressure. The crude product was purified by flash column chromatography (silica gel, 4:1 hexane:DCM) to afford pure Compound 5 as a white solid (2.447 g, 78%). R_{f}=0.15 (4:1 hexane:DCM). FTIR (neat) 3047, 2936, 2537, 2212, 1604, 1549 cm⁻¹. ¹H NMR (500 MHz, CDCl₃) δ 7.55-7.50 (m, 6H), 6.89 (d, J=8.9 Hz, 4H), 3.98 (t, J=6.6 Hz, 4H), 1.83-1.76 (m, 6H), 1.51-1.43 (m, 4H), 1.39-1.31 (m, 8H), 0.95-0.88 (m, 6H) ppm (FIG. 19). ¹³C NMR (126 MHz, CDCl₃) δ 160.0, 133.43, 133.39, 133.0, 121.4, 114.8, 114.3, 105.8, 95.0, 89.9, 68.3, 31.7, 29.3, 25.8, 22.7, 14.2 ppm (FIG. 20). HRMS (APPI) m/z calculated [C₃₄H₃₆BrIO₃]⁺ 682.0938; found 682.0924.

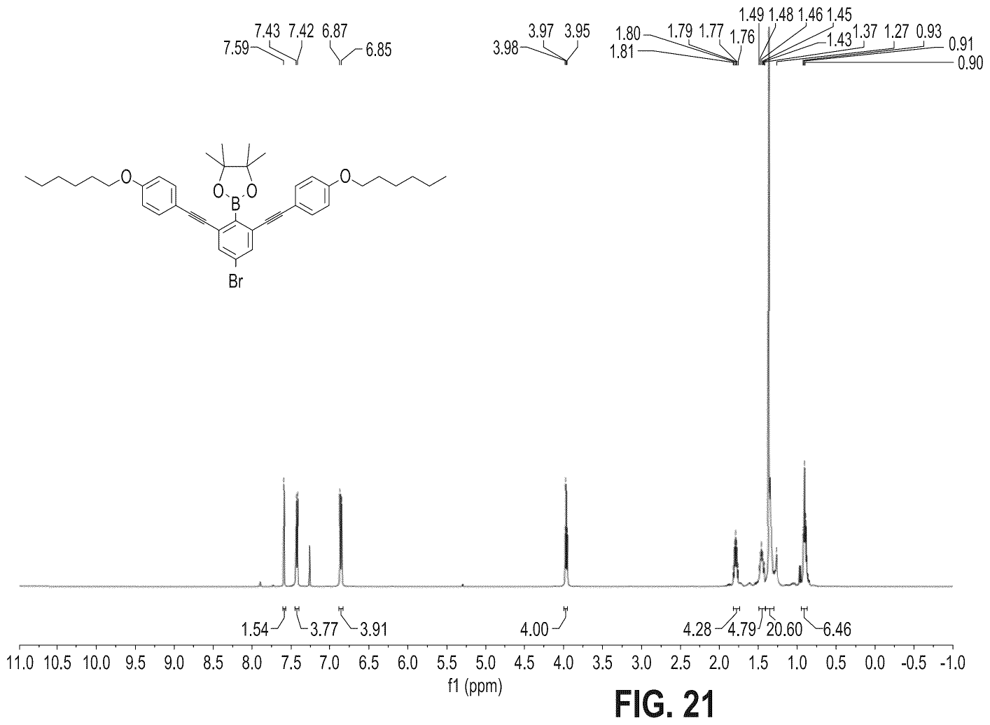

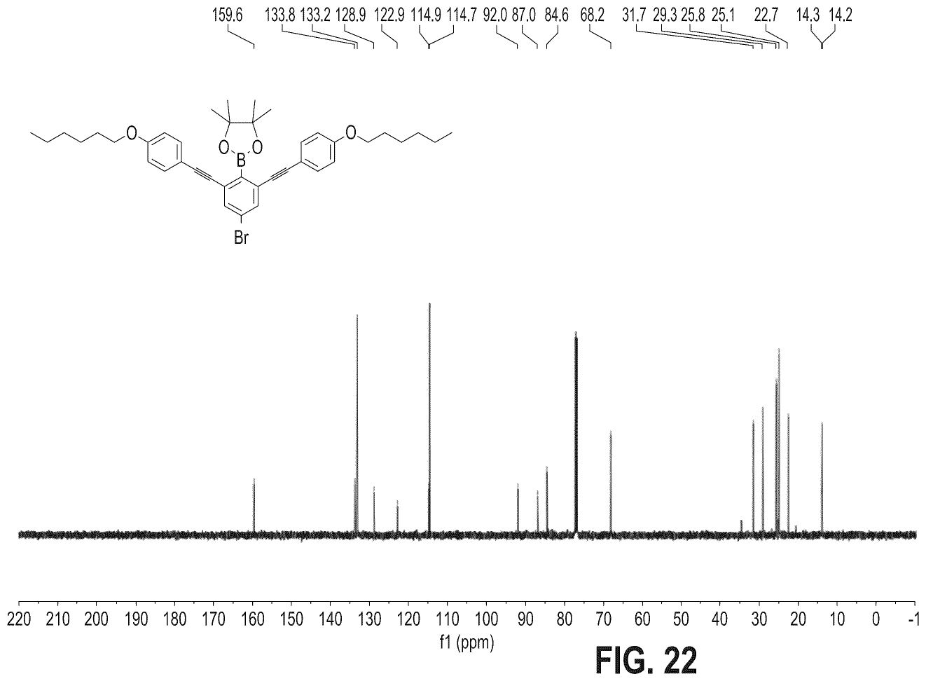

Synthesis of Compound 6: In a flame-dried flask, Compound 5 (1.022 g, 1.495 mmol, 1.0 equiv.) was dried by gentle heating under vacuum. Compound 5 was dissolved in 50 mL anhydrous THF and the solution was cooled to −78° C. while bubbling nitrogen gas through the solution for 10 minutes. ⁿBuLi (2.5 M in hexanes, 0.64 mL, 1.6 mmol, 1.1 equiv.) was added dropwise over 1 minute and the solution was allowed to slowly warm to 0° C. Upon reaching 0° C., 4,4,5,5-tetramethyl-2-(1-methylethoxy)-1,3,2-dioxaborolane (514 mg, 2.76 mmol, 1.8 equiv.) was added slowly and the solution was allowed to warm to room temperature. After 1 hour, the reaction was quenched with water and diluted with ethyl acetate. The layers are separated, and the organic layer was washed with brine, dried over anhydrous Na₂SO₄, and filtered. Solvent was removed under reduced pressure. The crude product was purified by flash column chromatography (silica gel, 2:1 hexane:DCM) to afford pure Compound 6 as a pale yellow solid (770 mg, 77%). R_{f}=0.14 (2:1 hexane:DCM). FTIR (neat) 2929, 2868, 2209, 1605, 1540, 1509 cm⁻¹. ¹H NMR (500 MHz, CDCl₃) δ 7.59 (s, 2H), 7.43 (d, J=8.5 Hz, 4H), 6.86 (d, J=8.7 Hz, 4H), 3.97 (t, J=6.5 Hz, 4H), 1.82-1.75 (m, 4H), 1.50-1.42 (m, 4H), 1.39-1.32 (m, 20H), 0.93-0.89 (m, 6H) ppm (FIG. 21). ¹³C NMR (126 MHz, CDCl₃) b 159.6, 133.8, 133.2, 128.9, 122.9, 114.9, 114.7, 92.0, 87.0, 84.6, 68.2, 31.7, 29.3, 25.8, 25.1, 22.7, 14.3, 14.2 ppm (FIG. 22). HRMS (APPI) m/z calculated [C₄₀H₄₈BBrO₄]⁺ 682.2824; found 682.2844.

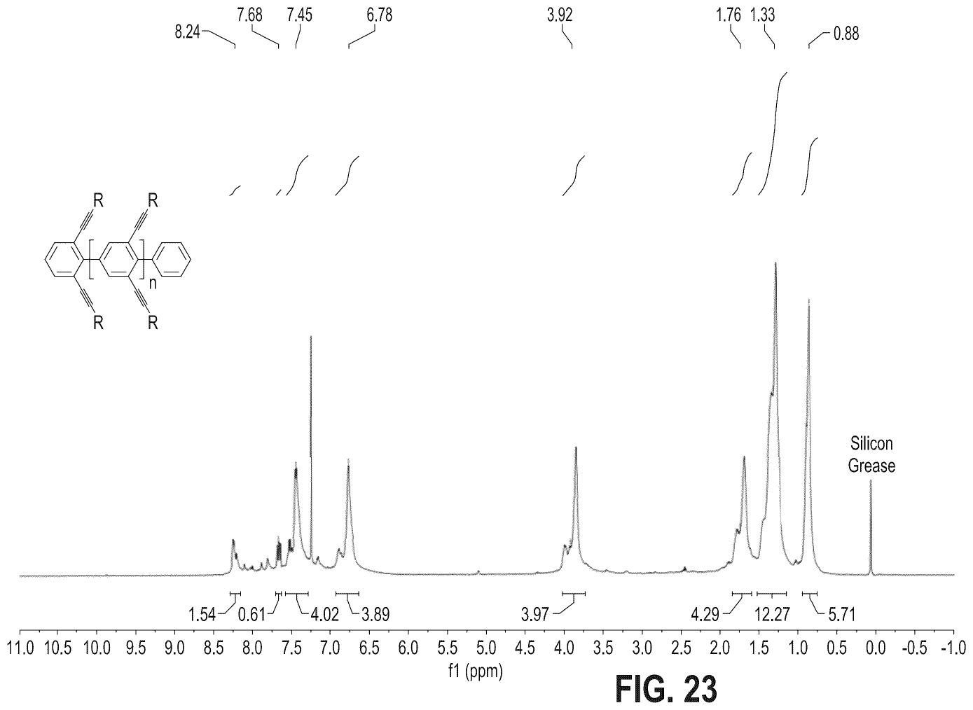

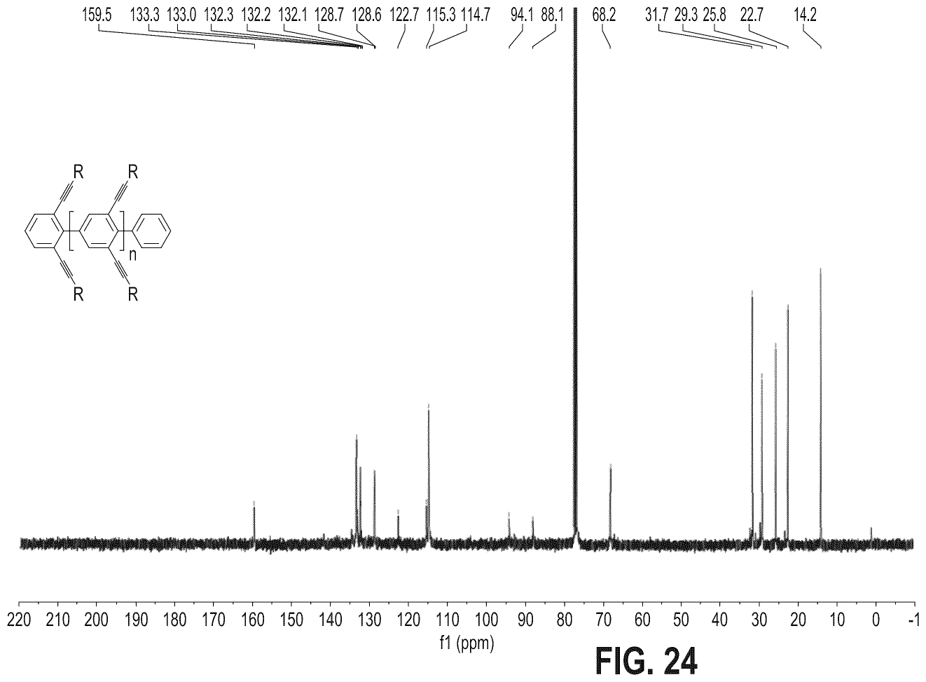

Synthesis of Compound 7: A solution of monomer 6 (230 mg, 0.336 mmol, 1.0 equiv.) and K₂CO₃ (830 mg, 6.01 mmol, 18 equiv.) in 15 mL THF and 2.5 mL water in a Schlenk tube was deoxygenated by bubbling nitrogen gas for 15 minutes. Pd(PPh₃)₄ (10 mg, 0.00865 mmol, 0.025) was added quickly and nitrogen gas was bubbled for another 2 minutes. The Schlenk tube was sealed under N₂ and stirred at 110° C. for 3 days. The solution was allowed to cool to approximately 65° C. and bromobenzene (48 mg, 0.306 mmol, 0.91 equiv.) was added. The solution was sealed under nitrogen gas and heated at 110° C. for a further 12 hours. The solution was cooled to room temperature and diluted with DCM. The layers are separated, and the organic layer was washed with water, washed with brine, dried over anhydrous Na₂SO₄, and filtered. Solvent was removed under reduced pressure. The crude polymer was washed three times with methanol to remove monomer and oligomers, affording Compound 7 (also referred to as “polymer 7”) (174 mg) as a brown solid. GPC (THF, 28° C.): Mₙ=7.3 kg mol⁻¹, M_{w}=10.7 kg mol⁻¹, PDI=1.5. FTIR (neat) 2928, 2860, 2209, 1604, 1508 cm⁻¹. ¹H NMR (500 MHz, CDCl₃) δ 8.29-8.19 (br, 1H), 7.70-7.64 (m, 1H), 7.58-7.32 (br, 4H), 6.95-6.65 (br, 4H), 4.04-3.75 (br, 4H), 1.86-1.61 (br, 4H), 1.53-1.15 (br, 12H), 0.97-0.77 (br, 6H) ppm (FIG. 23). ¹³C NMR (101 MHz, CDCl₃) δ 159.5, 133.3 (br), 133.0, 132.3, 132.2, 132.1, 128.7, 128.6, 122.7, 115.3, 114.7 (br), 94.1, 88.1, 68.2, 31.7, 29.3, 25.8, 22.7, 14.2 ppm (FIG. 24).

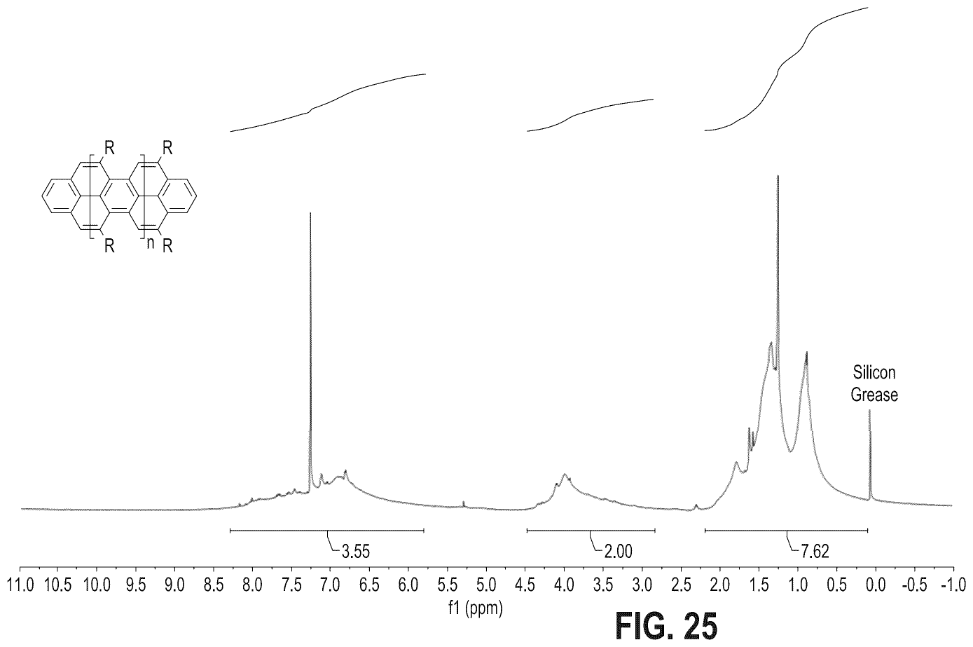

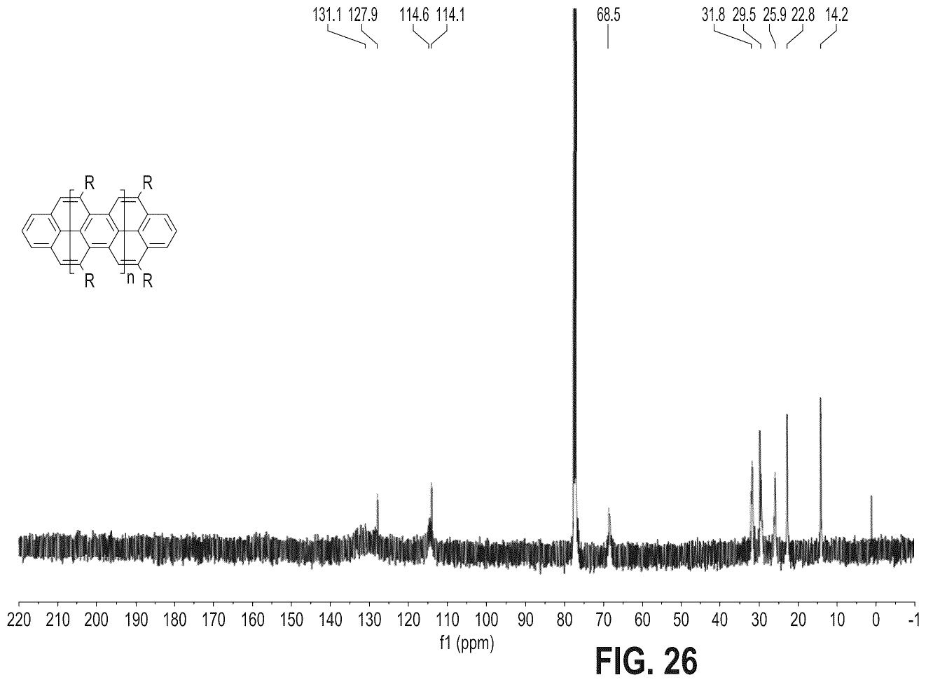

Synthesis of Compound 8: In a flame-dried flask, Polymer 7 (43 mg) was dissolved in 40 mL anhydrous DCM. Trifluoroacetic acid (0.75 mL) was added, and the solution was stirred under N₂ for 24 h. The reaction was cooled to −40° C. and 5 drops of triflic acid are added. The solution stirred at −40° C. for 30 min and was quenched with saturated NaHCO₃ solution at 0° C. The solution was allowed to warm to room temperature and the organic layer was washed three times with 100 mL of water to remove trifluoroacetate and triflate salts, washed with brine, dried over anhydrous MgSO₄, and filtered. The solvent was removed under reduced pressure to afford GNR 8 (36 mg, 84%) as black solids. GPC (THF, 28° C.): Mₙ=7.3 kg mol⁻¹, M_{w}=10.6 kg mol⁻¹, PDI=1.5. FTIR (neat) 2929, 2864, 2210, 1605, 1508 cm⁻¹. ¹H NMR (500 MHz, CDCl₃) δ 8.27-5.80 (br, 4H), 4.48-2.86 (br, 2H), 2.18-0.07 (br, 8H) ppm (FIG. 25). ¹³C NMR (125 MHz, CDCl₃) δ 131.1 (br), 127.9, 114.6 (br), 114.1, 68.5 (br), 31.8 (br), 29.5 (br), 25.9 (br), 22.8 (br), 14.2 (br) ppm (FIG. 26). From the MW of 8 (GNR), these ribbons are estimated to be 10.7 nm (23 repeating units) in length on average, and the consistent PDI shows very little intermolecular reactions during benzannulation.

Device fabrication: Pre-patterned ITO coated glass substrates (Xin Yan) are cleaned via sequential sonication for 10 minutes in deionized water, acetone, and isopropanol. Substrates are dried on a hotplate at 100° C. for one minute before plasma cleaning for 10 minutes. Cleaned substrates are loaded into an Angstrom Engineering thermal vapor deposition chamber and 10 nm of MoO₃ (Alfa Aesar) was deposited at a base pressure of 3E⁻⁶ torr. Graphene nanoribbons are dissolved in 1,2,4-trichlorobenzene (Sigma Aldrich) at concentrations from 0.5 to 5 mgmL⁻¹ and stirred overnight prior to use. GNR films are spin-coated on top of the MoO₃ at 2000 rpm to yield GNR thin films with thicknesses ranging from 3.0 nm to 9.0 nm as measured by variable angle spectroscopic ellipsometry (Woollam Ellipsometer) on Si substrates. Substrates with the GNR thin film are loaded into the deposition chamber where 40 nm of C₆₀ (MER Corp.), 7.5 nm BCP (Luminescence Technology, Inc.), and 80 nm Ag (Kurt J Lesker Co.) are deposited to complete the device stack. A special mask was used for Ag deposition to define an active area of 4.43 mm². Control devices are fabricated as described above without the GNR layer.

Device testing: Current-voltage (J-V) curves are acquired under illumination from a Xe arc lamp with intensity calibrated to 1-sun with a NREL-calibrated Si reference cell with KG5 filter. EQE measurements are made with monochromated light from a tungsten halogen lamp chopped at 200 Hz. A Newport-calibrated Si diode was used to calibrate the system prior to taking EQE measurements.

Statistical analysis: Error bars for all J-V plots represent the standard deviation of a minimum of five devices for each GNR thickness.

Optical measurements: Large area ITO coated glass substrates (1.5″×1.5) are cleaned via sequential sonication for 10 minutes in deionized water, acetone, and isopropanol. Substrates are dried on a hotplate at 100° C. for one minute before plasma cleaning for 10 minutes. The full device stack was created on the substrates as described in the device fabrication section. A Perkin Elmer Lambda 900 UV/VIS/NIR spectrometer was used to make reflection measurements of the devices. The reference slot was empty for the measurements. For solution measurements, GNRs are dissolved in 1,2,4-trichlorobenzene at 0.01 to 0.5 mgmL⁻¹ and a quartz cuvette was used as a solution holder. The reference slot was filled with pure 1,2,4-trichlorobenzene in a second cuvette.

Hole mobility measurements: Hole only devices are fabricated on the same ITO printed glass substrates (Xin Yan) used for devices. 50 nm MoO₃ (Alfa Aesar) was grown on the substrates at 3E⁻⁶ torr after sonication and plasma cleaning. 10 mgmL⁻¹ GNR in 1,2,4-trichlorbenzene (Sigma Aldrich) was spun at 2000 rpm to give 20 nm films. 50 nm MoO₃ was grown on top of the GNR and finally 80 nm Ag (Kurt J Lesker Co.) was grown using a mask to define the active area of 4.43 mm². J-V testing was performed in the dark by sweeping the voltage from −3 to 3 V. OriginPro was used to fit the device data with the Mott-Gurney equation for Space Charge Limited Current and extract the hole mobility.

Optical modeling: Transfer matrix modeling was performed in MATLAB to calculate absorption and EQE based on the device structure and optical constants obtained from ellipsometry. The electric field and exciton generation rate are calculated as a function of wavelength and position within the device stack. Charge collection and exciton diffusion length analysis based on EQE fitting was done simultaneously for all GNR thickness dependent EQE data.

Bandgap calculations: Materials Studio was used to calculate the bandgap and orbital energy levels of pentacene and GNR with 3 and 6 repeating units. GNR side chains are hydrogen terminated at the oxygen atom. This assumption was made based on the understanding that side chains are implemented for solubility and should not affect the conjugated network of sp² hybridized carbon that makes up the GNR core and the frontier molecular orbitals. Chemical structures are made in BIOVIA Draw and imported to Materials Studio. Forcite geometry optimization calculations are run first on each structure with a universal forcefield. DMol3 energy calculations aer run at medium quality with a DND basis set and a variety of functionals including GGA-PBE with Grimme DFT-D corrections, B3LYP with Grimme DFT-D corrections, m-GGA M06-L, and LDA PWC. GGA-PBE with Grimme produced the most accurate results and was used for the calculations reported in this work. Pentacene was used as a control compound, with an established bandgap of 1.9 eV and HOMO at −4.9 eV, that features a chain of sp² hybridized carbon. Pentacene was calculated to have a bandgap of 1.1 eV and a HOMO level of −4.04 eV, yielding a bandgap correction factor of 1.75, and a HOMO shift of −0.86 eV for the GNRs studied computationally. 3-GNR and 6-GNR had calculated bandgaps of 1.15 and 0.64 eV, and corrected bandgaps of 2.0 and 1.1 eV. This underestimation of the GNR bandgap in calculations has also been observed, wherein experimental bandgaps of a chevron GNR and a fluorenone GNR are 2.53 and 2.33 eV, respectively, while the calculated bandgaps are 1.6 and 1.4 eV.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the FIGS. Spatially relative terms may be intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A photovoltaic device comprising:
a substrate;
a first electrode on a surface of the substrate;
a second electrode; and
a first photoactive layer between the first electrode and the second electrode, the first photoactive layer including graphene nanoribbons (GNRs).

2. The photovoltaic device of claim 1, wherein the first photoactive layer is neat.

3. The photovoltaic device of claim 1, wherein the first photoactive layer includes GNRs admixed with another photoactive material.

4. The photovoltaic device of claim 1, wherein the first photoactive layer defines a thickness ranging from 2 nm to 1000 nm.

5. The photovoltaic device of claim 1, wherein the GNR is a semiconductor.

6. The photovoltaic device of claim 1, wherein at least a portion of the GNRs include edge groups.

7. The photovoltaic device of claim 6, wherein the edge groups include hydrogen, a halogen, an alkyl chain, or a thiophene chain, or any combination thereof.

8. The photovoltaic device of claim 6, wherein the edge groups include 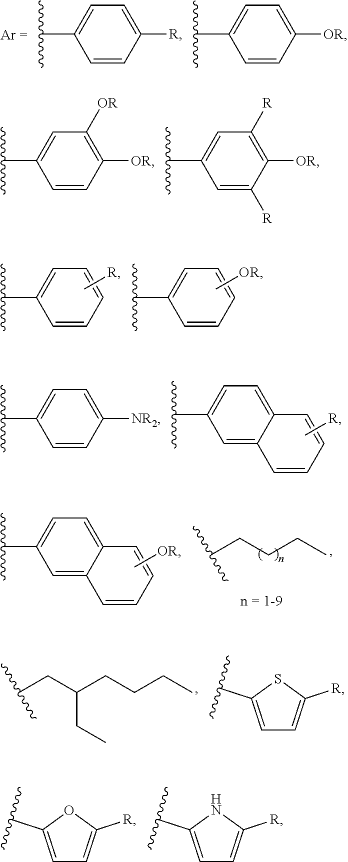
or any combination thereof.

9. The photovoltaic device of claim 1, wherein the GNRs have an external quantum efficiency (EQE) of greater than or equal to 0.5%.

10. The photovoltaic device of claim 1, further comprising:
a second photoactive layer.

11. The photovoltaic device of claim 10, wherein the second photoactive layer defines a thickness ranging from 5 nm to 200 nm.

12. The photovoltaic device of claim 10, wherein
the first photoactive layer is a donor layer, and
the second photoactive layer is an acceptor layer.

13. The photovoltaic device of claim 12, wherein second photoactive layer includes C₆₀.

14. The photovoltaic device of claim 10, wherein
the first photoactive layer is an acceptor layer, and
the second photoactive layer is a donor layer.

15. The photovoltaic device of claim 1, wherein the first photoactive layer consists essentially of GNRs.

16. The photovoltaic device of claim 1, wherein the first photoactive layer has an exciton diffusion length ranging from 10 nm to 300 nm.

17. The photovoltaic device of claim 1, wherein the first photoactive layer has a charge collection length ranging from 10 nm to 10,000 nm.

18. The photovoltaic device of claim 1, wherein the GNRs define an average length ranging from 1 nm to 100,000 nm.

19. The photovoltaic device of claim 1, wherein the GNRs define a core average width of 0.25 nm to 100 nm.

20. The photovoltaic device of claim 1, wherein the GNRs have a bandgap of greater than or equal to 0.1 eV.

21. The photovoltaic device of claim 1, wherein the GNRs have a bandgap of greater than or equal to 0.2 eV to less than or equal to 2.5 eV.

22. The photovoltaic device of claim 1, wherein the GNRs have less than 1 edge defect per 1 nm of length.

23. The photovoltaic device of claim 1, wherein
each of the GNRs defines a length and a width,
each of the GNRs includes a quantity of benzene rings across the width, and
the quantity ranges from 1 to 100 benzene rings.

24. The photovoltaic device of claim 1, wherein greater than or equal to 50% of the GNRs are oriented within 20% of perpendicular to the substrate.

25. The photovoltaic device of claim 1, wherein greater than or equal to 50% of the GNRs are oriented within 20% of parallel to the substrate.

26. The photovoltaic device of claim 1, further comprising:
an adjunct layer including a hole transport layer, an electron blocking layer, a buffer layer, an electron transport layer, a hole blocking layer, an electron extraction or any combination thereof.

27. The photovoltaic device of claim 26, wherein the adjunct layer includes
a hole transport layer, and
an electron transport layer.

28. A photovoltaic device comprising:
a first electrode;
a second electrode;
a donor layer between the first electrode and the second electrode, the donor layer including graphene nanoribbons (GNRs);
an acceptor layer between the donor layer and the second electrode;
a hole transport layer between the donor layer and the first electrode; and
an electron transport layer between the acceptor layer and the second electrode.
